(19) United States
(12) Patent Application Publication
(10) Pub. No.: US 2024/0232595 A1
(43) Pub. Date: Jul. 11, 2024

(54) METHOD AND APPARATUS WITH NEURAL NETWORK CIRCUITRY

(71) Applicants: SAMSUNG ELECTRONICS CO., LTD., Suwon-si (KR); Research & Business Foundation SUNGKYUNKWAN UNIVERSITY, Suwon-si (KR)

(72) Inventors: Jung-Hoon CHUN, Suwon-si (KR); Jiho SONG, Suwon-si (KR); Yoonmyung LEE, Suwon-si (KR); Jua LEE, Suwon-si (KR)

(73) Assignees: SAMSUNG ELECTRONICS CO., LTD., Suwon-si (KR); Research & Business Foundation SUNGKYUNKWAN UNIVERSITY, Suwon-si (KR)

(21) Appl. No.: 18/334,516

(22) Filed: Jun. 14, 2023

(30) Foreign Application Priority Data
Jan. 3, 2023 (KR) 10-2023-0000807

(51) Int. Cl. G06N 3/063

(52) U.S. Cl. CPC G06N 3/063

(57) ABSTRACT

An electronic device with neural network circuitry is provided. The neural network circuit includes a synaptic memory cell including a memory element disposed along an output line and configured to, dependent on the memory element and an input signal applied to an input line, generate a column signal on the output line; a reference memory cell comprising a reference memory element disposed along a reference line, and configured to, dependent on the reference memory element and the input signal, generate a reference signal on the reference line; and a first neuron circuit configured to generate an output signal based on the column signal and the reference signal, and determine a start voltage of an integration to be performed based on the output signal in response to a previous firing by the first neuron circuit with respect to a previous input signal or another firing performed by a second neuron circuit.

### CROSS-REFERENCE TO RELATED APPLICATIONS

This application claims priority under 35 USC § 119(a) to Korean Patent Application No. 10-2023-0000807 filed on Jan. 3, 2023, in the Korean Intellectual Property Office, the disclosure of which is incorporated by reference herein in its entirety.

### BACKGROUND

### 1. Field

The following description relates to a method and device with neural network circuitry.

### 2. Description of Related Art

In a von Neumann computer architecture, frequent movements of massive amounts of data between a processor and a memory may cause a long delay and a great power consumption, thus limiting chip performance. Currently, some deep neural network operations, accelerator are performed through a combination of a processor and computer readable instructions that configure the processor to perform digital computational operations of multiply and accumulate (MAC) and activation operations, for example, such as through a high-performance central processing unit (CPU), a graphics processing unit (GPU), an application-specific integrated circuit (ASIC), and the like.

A neuromorphic architecture may be used to perform operations directly in-memory at a position in a memory device in which input data may be provided or stored, and where information of connection strengths (e.g., synaptic weights) between neuron circuits in the memory device may be stored and updated.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an electronic device with neural network circuitry includes a synaptic memory cell comprising a memory element disposed along an output line within the neural network circuitry, and configured to, dependent on the memory element and an input signal applied to an input line within the neural network circuitry, perform a generation of a column signal on the output line; a reference memory cell comprising a reference memory element disposed along a reference line within the neural network circuitry, and configured to, dependent on the reference memory element and the input signal, perform a generation of a reference signal on the reference line; and a first neuron circuit configured to generate an output signal based on the column signal and the reference signal, and determine a start voltage of an integration that is to be performed based on the output signal in response to a previous firing by the first neuron circuit with respect to a previous input signal or another firing performed by a second neuron circuit.

The first neuron circuit may be configured to determine the start voltage as a first voltage based on the other firing, determine the start voltage as a second voltage based on the previous firing, and determine the start voltage as a third voltage in response to the input signal being a signal that is initially applied to the input line.

Among the first voltage, the second voltage, and the third voltage, the third voltage may be a largest voltage and the first voltage is a smallest voltage.

The first neuron circuit may be configured to determine the start voltage as a fourth voltage, in response to the other firing not being performed by the second neuron circuit, the previous firing not being performed by the first neuron circuit based on the previous input signal, and the input signal not being the signal initially applied to the input line.

The first neuron circuit may be configured to perform a leakage operation when a voltage integrated from the determined start voltage based on the output signal does not meet a threshold voltage, and perform a firing when the integrated voltage meets the threshold voltage.

The memory element may be configured to have a first resistance value at one time and a second resistance value at another time.

The first neuron circuit may be configured to generate, as the output signal, a current corresponding to a positive integer multiple of a net current which is a difference between a first current that is based on the memory element having the first resistance value and a second current that is based on the memory element having the second resistance value.

The first neuron circuit may be configured to generate, as the output signal, a current corresponding to a negative integer multiple of a net current which is a difference between a first current that is based on the memory element having the first resistance value and a second current that is based on the memory element having the second resistance value.

The first neuron circuit may be configured to generate an integrated column signal by integrating column signals for respective bits of the synaptic memory cell, generate an integrated reference signal by integrating reference signals for respective bits of the reference memory cell, and generate the output signal corresponding to a difference between the integrated column signal and the integrated reference signal.

The electronic device may further include a threshold memory array comprising a plurality of memory elements of which at least one memory element set based on a threshold value among the plurality of memory elements is configured to have a first resistance value; and an additional reference memory cell configured to share a reference wordline with the threshold memory array and comprising an additional reference memory element disposed along the reference wordline and configured to have a second resistance value.

The first neuron circuit may include a first capacitor configured to convert a current corresponding to the output signal to a first capacitor voltage; and an operational amplifier configured to receive the first capacitor voltage and the determined start voltage, and output a voltage.

The first neuron circuit may include one or more switches; and one or more second capacitors that are connected in parallel with the first capacitor through the one or more switches, wherein the first neuron circuit is configured to turn on all or some of the one or more switches in response to the other firing being performed by the second neuron circuit.

The electronic device may include a current mirror configured to copy the column signal based on a first copy ratio, and copy the reference signal based on a second copy ratio.

The electronic device may be further configured to adjust at least one of the first copy ratio and the second copy ratio in response to the other firing being performed by the second neuron circuit.

The electronic device may include a first window signal generation circuit configured to generate a first window signal to set a time interval for which the integration is performed; a second window signal generation circuit configured to generate a second window signal having a pulse width less than a pulse width of the first window signal; and a selection circuit configured to transmit the second window signal to the first neuron circuit in response to the other firing being performed by the second neuron circuit and transmit the first window signal to the first neuron circuit in response to the other firing not being performed by the second neuron circuit.

The synaptic memory cell may include resistive memory elements corresponding to a number of bits that represent a synaptic weight assigned to the synaptic memory cell, wherein the resistive memory elements are arranged along the same input line.

The reference memory cell may include reference memory elements corresponding to the number of bits, wherein the reference memory elements are arranged along the input line.

In a general aspect a method of operating a neural network circuit, includes performing a generation of a column signal on an output line within the neural network circuitry dependent on a memory element of a synaptic memory cell to which an input signal is applied to an input line within the neural network circuitry among one or more memory cells arranged along the output line and on the input signal; performing a generation of a reference signal on a reference line within the neural network circuitry dependent on a reference memory element of a reference memory cell to which the input signal is applied among one or more memory cells arranged along the reference line and on the input signal; generating, by a first neuron circuit, an output signal based on the column signal and the reference signal; and determining a start voltage of an integration that is to be performed based on the output signal, in response to a previous firing by the first neuron circuit with respect to a previous input signal or another firing being performed by a second neuron circuit.

The determining of the start voltage may include determining the start voltage as a first voltage based on the other firing, determining the start voltage as a second voltage based on the previous firing, and determining the start voltage as a third voltage in response to the input signal being a signal that is initially applied to the input line.

The determining may include determining the start voltage as a fourth voltage, in response to the other firing not being performed by the second neuron circuit, the previous firing not being performed by the first neuron circuit based on the previous input signal, and the input signal not being the signal initially applied to the input line.

Other features and aspects will be apparent from the following detailed description, the drawings, and the claims.

### BRIEF DESCRIPTION OF DRAWINGS

FIG. 1A illustrates an example electronic device with a neural network circuit, in accordance with one or more embodiments.

FIG. 1B illustrates an example synaptic memory cell and an example readout circuit, in accordance with one or more embodiments.

FIG. 2 illustrates example operations of a neuron circuit of an example neural network circuit, in accordance with one or more embodiments.

FIGS. 3A and 3B illustrate an example neuron circuit in an example neural network circuit, in accordance with one or more embodiments.

FIG. 4 illustrates an example threshold generation circuit and an additional reference circuit included in an example neural network circuit, in accordance with one or more embodiments.

FIGS. 5, and 6A and 6B illustrate example comparisons of firings using a net signal generated from a synaptic memory column, a reference column, a threshold generation column, and an additional reference column, in accordance with one or more embodiments.

FIG. 7 illustrates an example threshold time generation circuit of an example neural network circuit, in accordance with one or more embodiments.

FIG. 8 illustrates example operations of example neuron circuits, in accordance with one or more embodiments.

FIG. 9 illustrates an example of implementing a lateral inhibition by an example neural network circuit, in accordance with one or more embodiments.

FIGS. 10A through 10D illustrate an example of implementing a lateral inhibition by a neural network circuit, in accordance with one or more embodiments.

FIGS. 11 and 12 illustrate an example of implementing a lateral inhibition by an example neural network circuit, in accordance with one or more embodiments.

FIG. 13 illustrates an example method of operating an example neural network circuit, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, orA, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

One or more examples herein include neuromorphic processors (e.g., including a neural network circuit or combinations of neural network circuits or circuitry) and neuromorphic operations of the neuromorphic processors being applied to AI, big data, sensor networks, pattern/object recognition, and the like, as non-limiting example. In one or more examples, neuromorphic architectures of the neural network circuit or circuitry may perform analog neural network operations (e.g., integration, or MAC, and/or activation operations, as non-limiting examples), and may further include the same in an analog memory device.

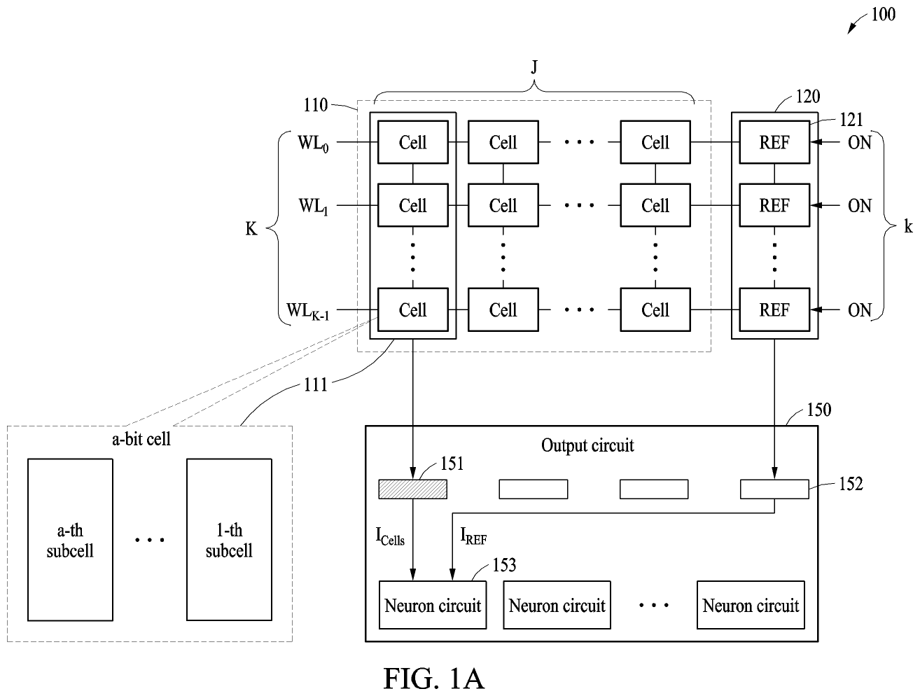

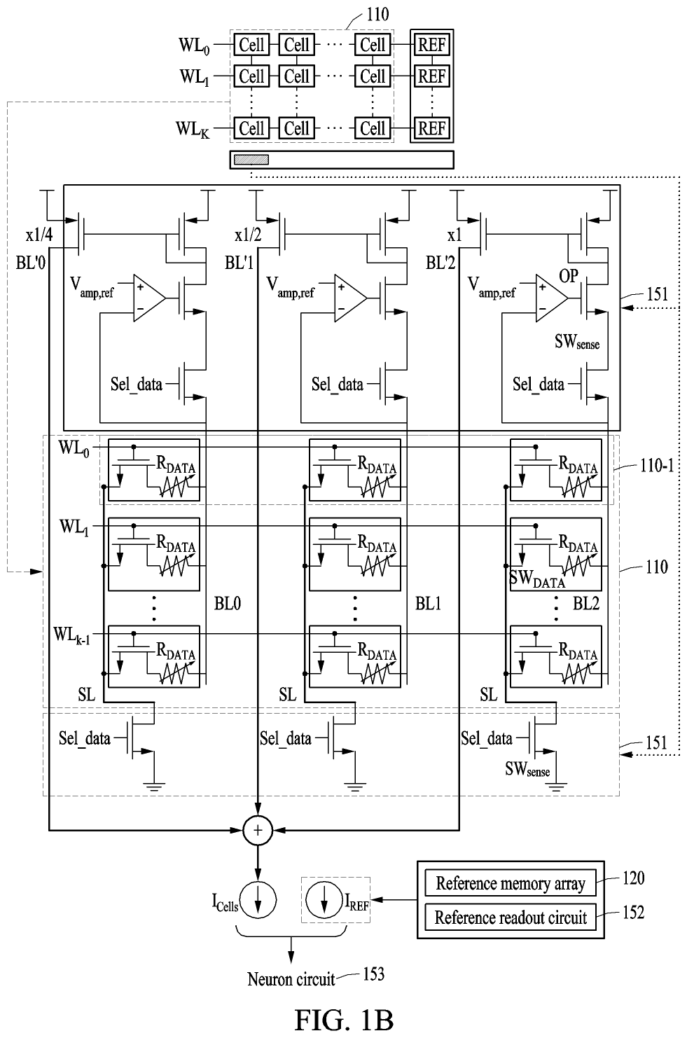

FIG. 1A illustrates an example electronic device and neural network circuit, in accordance with one or more embodiments. The neural network circuit 100 may also be referred to as an electronic device.

In an example, a neural network circuit 100 may be implemented as a circuit that performs neural network operations through connections between neuron circuits of a previous layer and neuron circuits of a target layer in a neural network, e.g., using weighted connections (i.e., synaptic weights). Examples include an electronic device with the neural network circuit 100. The neural network circuit 100 may also be referred to as an electronic device. The electronic device may be as non-limiting examples, a smartphone, a tablet, a server computer, and the like, with the processor, memory, sensors, and display providing functionalities of the same, and controlling of implementations of one or more neural networks, or portions thereof, and provision of data to the neural network circuit 100, and the reception of neural network results from the neural network circuit 100. In an example, the neural network circuit 100 is a portion of a memory of a memory device of the electronic device.

An output circuit 150 of the neural network circuit 100 may include a circuit that outputs the respective activations of neurons which are activation functions of a typical neural network. Briefly, any such reference herein to “synapses” or “neurons” are not intended to impart any relatedness with respect to how the neural network architecture using the neural network circuitry may ultimately computationally map or thereby intuitively recognize or consider information, and how a human's neurons operate. In other words, the terms “synapses” and “neuron” is merely a term of art referring to the hardware connection implemented operations of connections/connection weights and nodes of the neural network and the neural network circuitry.

The neural network may include a plurality of layers each having a plurality of nodes, and a previous layer may be a layer connected before a target layer in the neural network. A plurality of neuron circuits in the output circuit 150 may correspond to nodes included in a target layer. The neural network circuit 100 may transmit a node value (e.g., an input value) output from a neuron circuit of a previous layer to a target neuron circuit of a target layer based on connection strengths (e.g., synaptic weights) between the neuron circuits. The target neuron circuit (e.g., a neuron circuit 153) of the target layer may have, as a node value, a result of an activation of a weighted sum that is based on node values received from previous neuron circuits of the previous layer connected to the target neuron circuit and synaptic weight values. Each of the neuron circuits of the neural network circuit 100 may operate as a spiking neural network (SNN) and may include, as an example, a leaky integrate-and-fire (LIF) circuit. In an example, through operation of plural neuron circuits, a spike time-dependent plasticity (STDP) may be provided. However, examples are not limited thereto, and the activation function of the neural network may also be implemented as a circuit implemented in a different manner.

In an example, the neural network circuit 100 may include a synaptic memory array 110, a reference memory array 120, and the output circuit 150. The synaptic memory array 110 and the reference memory array 120 may be collectively referred to as a memory array.

The synaptic memory array 110 may be a magnetic random-access memory (MRAM), but examples of which are not limited thereto. In an example, the synaptic memory array 110 may correspond to another memory that is not the MRAM, such as, for example, a static RAM (SRAM) or a dynamic RAM (DRAM).

The synaptic memory array 110 may include a plurality of synaptic memory cells 111 arranged along input lines and output lines. The plurality of synaptic memory cells 111 may be arranged in the form of a crossbar array. The input lines may each be a line that receives an input, illustrated as K wordlines WL₀ to WL_{K-1} in FIG. 1A, where K may be an integer greater than or equal to 1. The output lines may each be a line that outputs an output signal indicating a result value, or a weighted sum, that is obtained through an accumulation (e.g., a multiply-accumulate (MAC) operation) of results of an operation (e.g., multiplication) between synaptic weights indicated by memory elements of synaptic memory cells 111 arranged along a corresponding output line and an input value indicated by each input signal. The output lines are illustrated as J lines in FIG. 1A, where J may be an integer greater than or equal to 1. For example, as illustrated, the synaptic memory array 110 may include K×J synaptic memory cells 111. That is, the neural network circuit 100 of FIG. 1A may also be construed as a circuit implementing a synaptic connection that connects K previous nodes and J subsequent nodes. When a synaptic weight is represented as “a” bits, each of the output lines may include “a” bitlines, where “a” may be an integer greater than or equal to 1. An output signal that is output from an output line may be a difference signal indicating a difference between a signal in which column signals (e.g., bit column signals) generated from bitlines included in the output line are integrated and a signal in which reference signals generated from reference lines are integrated.

An input line may receive an input signal through or from a pre-synaptic circuit. The pre-synaptic circuit may receive an output of a previous node (e.g., a previous neuron circuit) of the neural network, and transmit the output to a synaptic memory element of a current node.

The pre-synaptic circuit may also be referred to as an axon circuit.

The output circuit 150 may correspond to a postsynaptic circuit.

An output line may be connected to the postsynaptic circuit and may transmit, to the postsynaptic circuit, a signal corresponding to an integration product between input signals and synaptic weights of synaptic memory elements connected to the output line. The postsynaptic circuit may fire or transmit the output signal corresponding to the integration product between the input signals and the synaptic weights to a subsequent node (e.g., a subsequent synaptic circuit). The postsynaptic circuit may also be referred to as a dendrite circuit and may be implemented as, for example, a LIF circuit to be described below.

An input signal may be a signal received through an input line. For example, when the neural network circuit 100 receives an input signal corresponding to a bit value of 1 from an input line, an input voltage may be applied to the input line. In another example, when an input signal of an input line indicates a bit value of zero (0), the neural network circuit 100 may deactivate the input line. That is, in an example, the neural network circuit 100 may not apply a voltage to the input line or the neural network circuit 100 may apply a voltage of 0 volts (V) to the input line. However, the input voltage applied for each bit value indicated by the input signal is not limited to the foregoing example. In the example of FIG. 1A, as an output from a previous layer, an activation value (e.g., a voltage corresponding to a bit value of 1) may be applied to k input lines among the K input lines illustrated in FIG. 1A, where k may be an integer greater than or equal to 0, and less than or equal to K.

A synaptic memory cell 111 may include memory elements arranged along an output line. The synaptic memory cell 111 may include resistive memory elements arranged along an output line, each having one of a first resistance value and a second resistance value, but examples of which are not limited thereto. The synaptic memory cell 111 may include resistive memory elements of a number of bits (or bit number) that represent a synaptic weight assigned to the synaptic memory cell 111. The bit number of resistive memory elements may be arranged along the same input line.

In response to receiving an input signal through an input line, a synaptic memory cell 111 may generate a column signal based on a memory element and the input signal. When the memory element is a resistive memory element, the first resistance value and the second resistance value may each be mapped to a binarized value. For example, the first resistance value and the second resistance value may indicate a bit value of “0” or “1”, respectively. For example, the first resistance value which corresponds to low resistance may indicate a bit value of “0,” and the second resistance value which corresponds to high resistance may indicate a bit value of “1.” However, examples are not limited thereto, and bit values mapped to the first resistance value and the second resistance value may vary according to different embodiments.

When a synaptic weight is represented as a bit sequence with multiple bits (i.e., a multi-bit sequence), a synaptic memory cell 111 may include a plurality of sub-cells. For example, the synaptic weight may be represented as a bit sequence of “a” bits. For the a-bit synaptic weight, the synaptic memory cell 111 may include “a” sub-cells. In this example, a first sub-cell may have a resistance value of a bit value corresponding to a position of a least significant bit (LSB) in a bit sequence representing the synaptic weight, and an ath sub-cell may have a resistance value of a bit value corresponding to a position of a most significant bit (MSB) in the bit sequence. Each of the “a” sub-cells may include a resistive memory element having a resistance value corresponding to a bit value of a corresponding bit position in the synaptic weight. The resistive memory element included in each of the “a” sub-cells may be set to have a resistance value mapped to a bit value of a corresponding bit position. For example, the resistive memory element may be set to have one of the first resistance value and the second resistance value. Hereinafter, an example of a synaptic memory cell implemented with 3-bit cells (e.g., the synaptic memory cell 111 implemented with 3-bit cells) will be described with reference to FIG. 1B.

A column signal described herein may be a single signal in which multiple signals output from synaptic memory cells 111 arranged along one column line in the synaptic memory array 110 are integrated. For example, a column signal may be a signal corresponding to an integration product between input values of input signals and bit values corresponding to resistive memory elements of sub-cells connected to the same bitline in the synaptic memory array 110. That is, a column signal of one bitline may be a signal corresponding to an integration product of a bit position represented by the bitline in an output line. As will be described below, the neural network circuit 100 may obtain a signal by multiplying and accumulating column signals of bitlines included in the same output line by a weight (e.g., a “bit weight” hereinafter) corresponding to a bit position of a corresponding bitline. In an example, a bit weight corresponding to an LSB may be ¼, a bit weight corresponding to a first bit position from the LSB may be ½, and a bit weight corresponding to a second bit position from the LSB may be 1. However, an assumption may be made that the bit weight of the second bit position from the LSB, which is an MSB, is 1, and thus the bit weight may not be input as the bit weight, and may vary based on an intended implementation. For the convenience of description, a column is mainly illustrated as a vertical line, but examples are not limited thereto, and examples include varying shapes of the column lines.

A resistive memory element may be an element that may have one of a first resistance value and a second resistance value. The resistive memory element may be, for example, an MRAM. The MRAM may have one of two states of a magnetic tunnel junction (MTJ). For example, the MRAM of a parallel (P) state may have the first resistance value, and the MRAM of an anti-parallel (AP) state may have the second resistance value. In a non-limiting example, the second resistance value may be greater than the first resistance value. The first resistance value and the second resistance value may also be referred to as a low resistance value and a high resistance value, respectively. The P state and the AP state may also be referred to as a low resistance state and a high resistance state, respectively. The MRAM may have a resistance ratio of the second resistance value to the first resistance value, which may be 2. However, the resistance ratio of the resistive memory element is not limited thereto, and the resistance ratio may vary depending on a type of element. The neural network circuit 100 may generate a net signal, using the reference memory array 120 to be described below, to discriminate signals output according to the first resistance value and the second resistance value of a resistive memory element.

For convenience of description, a resistive memory element of the P state and the AP state is mainly described herein, but examples are not limited thereto. Unless otherwise described, the P state may also be construed as a state having the first resistance value, and the AP state may also be construed as a state having the second resistance value.

The reference memory array 120 may include a plurality of reference memory cells 121 arranged along a reference line. In the example of FIG. 1A, the reference memory cells 121 included in the reference memory array 120 may be arranged along the reference line. The reference memory array 120 may include the same number of reference memory cells 121 as the input lines.

A reference memory cell 121 may include reference memory elements arranged along the reference line. For example, the reference memory elements may each have a programmable resistance value based on a determined implementation, but is not limited thereto. In this example, having the “programmable” resistance value may indicate that a resistance value is dynamically changeable. The reference memory cell 121 may include reference memory elements of the number of bits (or bit number) for representing a synaptic weight. The bit number of reference memory elements may be arranged along the same input line.

In an example, each reference memory cell 121 may include reference sub-cells of the number of bits, i.e., memory elements of the number of bits, similarly to each synaptic memory cell 111 described above. For example, a reference memory cell 121 may include a resistive memory element set to have a preset resistance value, for example, the first resistance value or the second resistance value.

In another example, each reference memory cell 121 may be a 1-bit cell that stores single-bit information (e.g., a sign bit), irrespective of the number of bits of a synaptic memory cell 111.

A reference memory cell 121 may generate a reference signal based on a reference memory element and an input signal. The reference signal may be a signal in which signals output from the reference memory cells 121 arranged along the reference line in the reference memory array 120 are integrated. The reference line may also include the same number of reference bitlines as bits. For example, the reference signal may be a signal corresponding to an integration product between input values of input signals and bit values corresponding to memory elements of reference sub-cells connected to the same reference bitline in the reference memory array 120. That is, a reference signal of a reference bitline may be a signal corresponding to an integration product of a bit position indicated by the reference bitline in the reference line.

The output circuit 150 may generate an output signal for an output line from the column signal output from synaptic memory cells 111 and the reference signal output from the reference memory cell 121. For example, the neural network circuit 100 may further include another synaptic memory cell disposed along another output line. In this example, the output circuit 150 may generate respective output signals for the output line and the other output line, respectively, using the same reference memory cell. That is, the output circuit 150 may use the same reference column signal to generate different output signals for respective output lines. An operation of the output circuit 150 will be described below.

In an example, during a synapse operation, the neural network circuit 100 may integrate all signals (e.g., current signals) generated for respective columns in response to an input to K wordlines to access synaptic memory elements. An output line may include bitlines corresponding to bit positions, and an integrated column signal I_{Cells} output from the output line may be a signal in which signals obtained by applying a bit weight to column signals of individual bitlines are integrated. The integrated column signal I_{Cells} may be expressed as Equation 1 below.

$${I}_{Cells} = {MI}_{P} + ( N - M ) {I}_{AP} \qquad Equation 1$$

In Equation 1, I_{P} denotes a current flowing in a resistive memory element of the P state (e.g., the first resistance value), and I_{AP} denotes a current flowing in a resistive memory element of the AP state (e.g., the second resistance value). The integrated column signal I_{Cells} may be a linear combination of I_{P} and I_{AP}. A synaptic readout circuit 151 of the output circuit 150 may generate the integrated column signal Cells.

$${I}_{REF} = {XI}_{P} + ( N - X ) {I}_{AP} \qquad Equation 2$$

Equation 2 may express a signal obtained by applying a bit weight for each bit position to a current signal flowing in a resistive memory element to which an input signal is applied among resistive memory elements included in the reference memory array 120. An integrated reference signal I_{REF} may be a signal obtained by applying a bit weight to reference signals for respective bit positions and integrating them. In Equation 2, X may be determined as any one of integers that are less than or equal to N and greater than or equal to 0 according to an implementation. For example, when a reference memory cell 121 is a 1-bit cell, X may have a value of 0 or N.

A reference readout circuit 152 of the output circuit 150 may generate the integrated reference signal I_{REF}. In Equations 1 and 2 above, coefficients N and M of the linear combination may be expressed by Equations 3 and 4 below.

$$N = k \cdot ( {2}^{a} - 1 ) \qquad Equation 3$$

$$M = {\sum }_{j = 0}^{k - 1} {\sum }_{i = 0}^{a - 1} {m}_{ij} \cdot {2}^{i} , where M \leq N , {m}_{ij} = 0 or 1 \qquad Equation 4$$

In the equations above, N denotes a value determined based on sub-cells connected to an activated wordline. k denotes the number of activated wordlines (e.g., input lines) as described above. “a” denotes the number of sub-cells included in each memory cell and the number of bits of a synaptic weight. For example, N may be a sum of values of power of 2 using, as an exponent, a bit position represented by each sub-cell included in a synaptic memory cell 111 connected to an activated wordline among synaptic memory cells 111 connected to an output line. M, which is an integer less than or equal to N, may be a value determined based on sub-cells of the P state (e.g., the first resistance value) among the synaptic memory cells 111 connected to the activated wordline. For example, m_{i,j} may be 1 when an ith synaptic memory cell has the first resistance value, and may be 0 when the ith synaptic memory cell has the second resistance value. For example, M may be k sums of values of power of 2 using, as an exponent, a bit position represented by a sub-cell in the P state in the synaptic memory cell 111 connected to the activated wordline among synaptic memory cells 111 connected to the output line.

$${I}_{net , column} = {I}_{Cells} - {I}_{REF} = ( M - X ) ( {I}_{P} - {I}_{AP} ) \qquad Equation 5$$

The output circuit 150 of the neural network circuit 100 may generate an output signal I_{net,column} corresponding to a difference between the integrated column signal I_{Cells} and the integrated reference signal I_{REF} based on Equation 5 above.

A difference (I_{P}−I_{AP}) between a first current I_{P} that is based on a resistive memory element of the first resistance value and a second current I_{AP} that is based on a resistive memory element of the second resistance value may be referred to as a valid signal or a net signal. Alternatively, I_{P}−I_{AP} may be a signal in the form of a current, and it may also be referred to as a net current. In this example, the output signal I_{net,column} may correspond to a (M−X) multiple of the net signal, where (M−X) may be a positive integer or a negative integer according to a value of X.

Although the neural network circuit 100 is described herein mainly as an SNN that implements a neural network that integrates currents according to a synaptic weight, examples are not limited thereto. The neural network circuit 100 may also be applied to a system that implements a MAC operation, such as, for example, a computation-in-memory (CIM) circuit and a vector matrix multiplication (VMM) circuit using a memory having a relatively low resistance ratio. Even if the resistance ratio between the low resistance and the high resistance of a resistive memory element included in the neural network circuit 100 is not great, an output value may be discriminated through the net signal described above. Even if the neural network circuit 100 uses a resistive memory element having the resistance ratio of the second resistance value to the first resistance value that exceeds 1, an output may be discriminated through the net signal. Therefore, constraints in an implementation for sensing and summation of currents output from a memory array may be reduced.

The neural network circuit 100 may have a memory array having a size that is increased by offsetting a high resistance state. Additionally, the neural network circuit 100 may be further applicable to a neural network processor that processes a large quantity of data.

As will be described in greater detail below, the neural network circuit 100 may implement, as a single synaptic memory array 110, two typical responses of the biological neural network—an excitatory postsynaptic potential (EPSP) with a potential increasing according to an input stimulus and an inhibitory postsynaptic potential (IPSP) with a potential decreasing according to an input stimulus. More specifically, the neural network circuit 100 may implement the EPSP that increases a voltage in response to the stimulus when the output signal I_{net,column} is proportional to a positive multiple of the net signal, and may implement the IPSP that decreases a voltage in response to the stimulus when the output signal I_{net,column} is proportional to a negative multiple of the net signal.

Additionally, as will be described in detail below, the neural network circuit 100 may implement a refractory period in which nodes respond insensitively to a consecutive input of stimuli to the neural network or neural network layer/portion and/or implement a lateral inhibition that inhibits a response of laterally connected other nodes when a node outputs an action potential (e.g., a firing).

Although the output circuit 150 is described herein as including a LIF circuit as an activation function circuit, examples are not limited thereto. For example, the neural network circuit 100 may include an analog-to-digital converter (ADC), instead of the LIF circuit, and convert the output signal from an analog signal to a digital value (e.g., output data). The electronic device including the neural network circuit 100 may also determine a value to be propagated to a subsequent node by applying an activation function to output data. That is, the electronic device may also perform an operation corresponding to the activation function at a digital level.

FIG. 1B illustrates an example of a synaptic memory cell and a readout circuit, in accordance with one or more embodiments.

In an example, the output circuit 150 of the neural network circuit 100 may include a synaptic readout circuit 151 and a neuron circuit 153 connected to the synaptic memory array 110. The output circuit 150 may also include a reference readout circuit 152 connected to the reference memory array 120. Although the synaptic readout circuit 151 is mainly described with reference to FIG. 1B, the reference readout circuit 152 may also have the same configuration as the synaptic readout circuit 151.

As illustrated in FIG. 1B, resistive memory elements of synaptic memory cells 110-1 connected to the same output line may be connected to each other in parallel. In an example, resistive memory elements connected to the same bitline among the synaptic memory cells 110-1 connected to the same output line may be connected to each other in parallel. Accordingly, current signals output from the resistive memory elements of the same bitline may be integrated along the output line.

In the example of FIG. 1B, a resistance of a resistive memory element is indicated as R_{DATA}. As described above, a resistive memory element to which an input signal is applied through wordlines WL₀ to WL_{K-1} among resistive memory elements arranged along bitlines BL0 to BL2 may generate a current signal according to a voltage applied to the resistive memory element. When the input signal is applied along the wordlines WL₀ to WL_{K-1}, a switch SW_{DATA} may be turned on.

A switch SWₛₑₙₛₑ (e.g., a transistor) may connect the resistive memory element to a sensing line SL. In this example, when a Sel_data signal is applied, the switch SWₛₑₙₛₑ (e.g., the transistor) is turned on, and the bitlines BL0 to BL2 and the sensing line SL may be connected to a supply voltage and the ground.

An operational amplifier (indicated as OP) may have a high gain and may fix a voltage of the bitlines BL0 to BL2 to V_{amp_ref} irrespective of a resistance value between the sensing line SL and the bitlines BL0 to BL2. That is, a voltage difference between the sensing line SL and the bitlines BL0 to BL2 may be maintained as constant. Each resistive memory element may generate, on the bitlines BL0 to BL2, a current (e.g., a column signal) determined according to the resistance R_{DATA} with respect to the fixed voltage V_{amp_ref} applied equally to both ends.

The synaptic readout circuit 151 may include a current mirror configured to copy a column signal for each bit of a synaptic memory cell 110-1 and a reference memory cell as a current of a multiple corresponding to a corresponding bit. For example, the current mirror of the synaptic readout circuit 151 may copy (or reproduce) a column signal generated in a bitline to other bitlines BL0 to BL2. The magnitude of the copied current may vary depending on a width of the transistor. As described above, the current mirror may copy a column signal at a current copy ratio corresponding to a bit weight. For example, in the example of FIG. 1B, a current may be copied by ¼ times, ½ times, and 1 times for the first bitline BL0, the second bitline BL1, and the third bitline BL2, respectively.

The synaptic readout circuit 151 may generate an integrated column signal I_{Cells} by integrating column signals for respective bits of synaptic memory cells 110-1, and may generate an integrated reference signal I_{REF} by integrating reference signals of respective bits of reference memory cells. In an example, the output circuit 150 may generate the integrated column signal I_{Cells} by accumulating copied currents from a column signal. The output circuit 150 may also generate the integrated reference signal I_{REF} for a reference signal through the reference readout circuit 152. For example, if a resistive memory element is implemented as an MRAM, a read disturbance may not occur only when a current flowing through an MTJ is small. Accordingly, an amplifier configured to process a relatively low common input may be desired. The neuron circuit 153 of the output circuit 150 may generate an output signal based on the integrated column signal I_{Cells} and the integrated reference signal I_{REF} and process the generated output signal. A structure and operation of the neuron circuit 153 will be described below.

The output circuit 150 may use the output signal which is a difference between the integrated column signal I_{Cells} and the integrated reference signal I_{REF} to accurately discriminate a signal even when there is one resistive memory element of the P state and a plurality of resistive memory elements of the AP state. The output circuit 150 may generate the integrated reference signal I_{REF} using a reference memory element having a programmable resistance value, and thus the output signal may also have a value corresponding to a negative integer multiple of a net signal, in addition to a positive integer multiple of the net signal. Accordingly, based on this, the output circuit 150 may represent an EPSP and an IPSP.

That is, the net signal is always a positive value, and thus the output signal being a positive integer multiple of the net signal may be construed that the integrated column signal I_{Cells} is greater than the integrated reference signal I_{REF}, and the output signal being a negative integer multiple of the net signal may be construed that the integrated column signal I_{Cells} is less than the integrated reference signal I_{REF}.

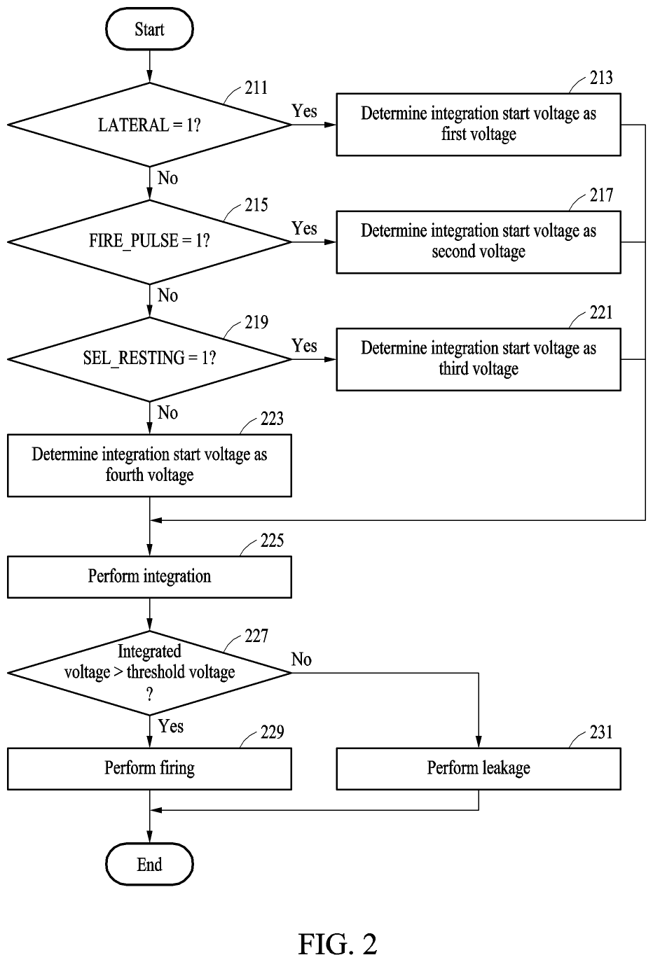

FIG. 2 illustrates an example of operations of a neuron circuit of a neural network circuit, in accordance with one or more embodiments. The operations in FIG. 2 may be performed in the sequence and manner as shown. However, the order of some operations may be changed, or some of the operations may be omitted, without departing from the spirit and scope. Additionally, some operations illustrated in FIG. 2 may be performed in parallel or simultaneously. In an example, the descriptions of FIGS. 1A-1B may also be applicable to FIG. 2 and are incorporated herein by reference. Thus, the above description may not be repeated here for brevity purposes.

There are two types of a postsynaptic potential (PSP): an EPSP in which a voltage increases in response to a stimulus, and an IPSP in which a voltage decreases in response to a stimulus. When a stimulus exceeding a threshold is transmitted from a previous or pre-neuron to a post-neuron or when a plurality of stimuli less than or equal to the threshold is transmitted several times within a short period of time, an action potential (firing) may occur. In biological neurons, this threshold is called a membrane potential of a neuron which is reset to a base potential upon firing by the neuron. The base potential may also be referred to as a resting potential. When a stimulus less than or equal to the threshold is transmitted from a pre-neuron to a post-neuron, a PSP may be generated instead of the action potential, and there may gradually be a leakage at the PSP until a subsequent stimulus is received.

When a neuron outputs the action potential in a biological neuron, it may respond insensitively or not respond to a subsequent stimulus. A period in which a neuron outputs the action potential in response to a stimulus and then responds insensitively or does not respond to a subsequent stimulus may be referred to as a “refractory period.” When the neuron outputs the action potential in the biological neural network, the response of other neurons connected laterally to the neuron may be inhibited, which may be referred to as a “lateral inhibition.”

While a neuron circuit (e.g., the neuron circuit 153 of FIGS. 1A and 1B) may implement an electronic firing and simulate leakage of a node, and simulate a lateral inhibition and a refractory period. These hardware implementations are substantially different from biological neuron biological mechanisms (e.g., where potential change depending on ion channel openings and closings in response to chemical neuro transmitting and other factors.

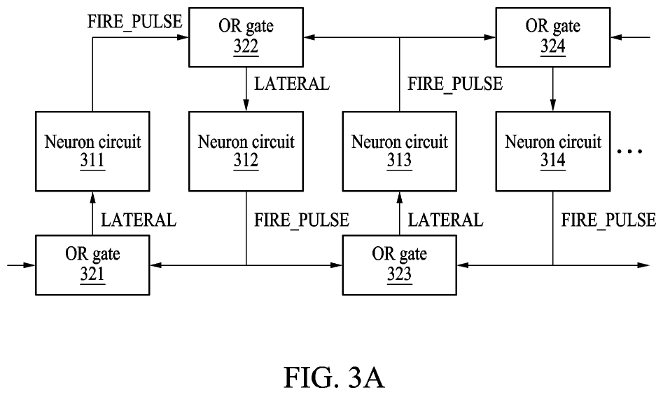

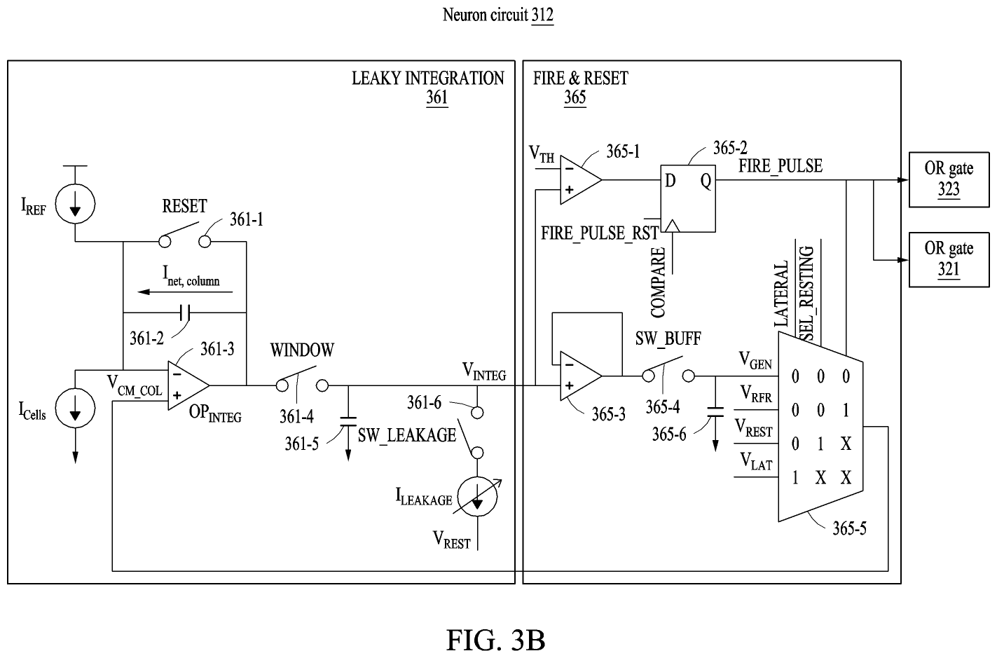

Referring to FIG. 2, in operation 211, the neuron circuit 153 may determine whether LATERAL=1. That LATERAL is 1 (i.e., LATERAL=1) indicates that there is a fire on another neuron circuit in a previous clock cycle. In operation 213, when LATERAL=1, the neuron circuit 153 may determine an integration start voltage (e.g., V _{CM_COL} of an operational amplifier OP_{INTEG} of FIG. 3B to be described below) as a first voltage V_{LAT}. As will be described below, an integration may refer to an operation of converting a current (e.g., the current I_{net,column} of Equation 5 above) to a voltage (e.g., V_{INTEG}).

In operation 215, when LATERAL is not 1 (i.e., LATERAL=0), the neuron circuit 153 may determine whether FIRE_PULSE=1. That FIRE_PULSE=1 may indicate that there is a fire on the neuron circuit 153 in the previous clock cycle.

In operation 217, when FIRE_PULSE=1, the neuron circuit 153 may determine the integration start voltage as a second voltage V_{RFR}.

When FIRE_PULSE is not 1 (i.e., FIRE_PULSE=0), the neuron circuit 153 may determine whether SEL_RESTING=1. That SEL_RESTING=1 may indicate that an input signal of a current clock cycle is an input signal that is the most initially applied to the neural network circuit 100. The neural network circuit 100 may set SEL_RESTING=1 when the input signal is most initially applied to an input line and may set SEL_RESTING=0 when the input signal is applied to the input line in a subsequent clock cycle.

In operation 221, when SEL_RESTING=1, the neuron circuit 153 may determine the integration start voltage as a third voltage V_{REST}. The third voltage V_{REST} may correspond to the resting potential in the biological neural network.

When SEL_RESTING is not 1 (i.e., SEL_RESTING=0), the neuron circuit 153 may determine the integration start voltage as a fourth voltage V_{GEN}. When a voltage generated as the neuron circuit 153 performs the integration in the previous clock cycle is less than a threshold voltage, the neuron circuit 153 may perform a leakage operation without a firing in the previous clock cycle. The voltage integrated by the leakage (e.g., V_{INTEG} to be described below) may change, and the neuron circuit 153 may hold the changed voltage. The neuron circuit 153 may determine the held voltage V_{GEN} as the integration start signal in the current clock cycle.

In the example of FIG. 2, operation 211 may precede operation 215, and operation 215 may precede operation 219. However, examples are not limited thereto, and the neuron circuit 153 may perform operations 211, 215, and 219 in parallel, or independently, and in any other order.

FIGS. 3A and 3B illustrate an example of a neuron circuit in a neural network circuit, in accordance with one or more embodiments.

Referring to FIG. 3A, the output circuit 150 may include a plurality of neuron circuits 311 to 314 and a plurality of OR gates 321 to 324. Each of the OR gates 321 to 324 may transmit a LATERAL signal (e.g., 1) to its own neuron circuit when there is a fire on each of other neuron circuits of its own neuron circuit. For example, when there is a fire on the neuron circuit 311 and/or the neuron circuit 313, the OR gate 322 may transmit the LATERAL signal (e.g., LATERAL=1) to the neuron circuit 312 of the OR gate 322. As will be described below with reference to FIG. 3B, when receiving the LATERAL signal from the OR gate 322, the neuron circuit 312 may determine or adjust an integration start voltage to be a first voltage. The integration start voltage may be adjusted to be lower than V_{REST}, and the neuron circuit 312 may thus inhibit a response even if there is an input signal in a current clock cycle.

In the example of FIG. 3A, a response of a specific neuron circuit (e.g., the neuron circuit 312) may be inhibited by a fire of each of two neighboring neuron circuits (e.g., the neuron circuits 311 and 313). This example is, however, illustrative only. According to an implementation of the neural network circuit 100, a fire of each of three or more neuron circuits may inhibit a response of a specific neuron circuit (e.g., the neuron circuit 312). Alternatively, the neural network circuit 100 may be implemented such that a firing by a neuron circuit far from a specific neuron circuit inhibits a response of the specific neuron circuit.

An example neuron circuit 312, in accordance with one or more embodiments, is illustrated in FIG. 3B. The following description of the neuron circuit 312 of FIG. 3B may also apply to the other neuron circuits 311, 313, and 314.

The example neuron circuit 312 may include a leakage portion circuit 361 and a fire and reset portion circuit 365.

An analog mux 365-5 of the fire portion circuit 365 may determine, adjust, or set an integration start voltage (e.g., V_{CM_COL} of an operational amplifier 361-3) according to a LATERAL signal, a FIRE_PULSE signal, or a SEL_RESTING signal. In an example, when receiving the LATERAL signal (e.g., LATERAL=1) from the OR gate 322 of FIG. 3A, the analog mux 365-5 may determine, adjust, or set the integration start voltage to be V_{LAT}. The analog mux 365-5 may receive the FIRE_PULSE signal (e.g., previous FIRE_PULSE=1) from a flip-flop 365-2 as the neuron circuit 312 performs a firing in a previous clock cycle. In this case, the analog mux 365-5 may determine, adjust, or set the integration start voltage to be V_{RFR}. When SEL_RESTING=1, the analog mux 365-5 may determine, adjust, or set the integration start voltage to be V_{REST}. When LATERAL=0 because other neuron circuits did not perform a firing in the previous clock cycle, previously FIRE_PULSE=0 because the neuron circuit 312 also did not perform a firing in the previous clock cycle, and SEL_RESTING=0, the analog mux 365-5 may determine or set the integration start voltage to be V_{GEN}.

In a current clock cycle, the leakage portion circuit 361 may receive an integrated column signal I_{Cells} and an integrated reference signal I_{REF} from a synaptic readout circuit (e.g., the synaptic readout circuit 151 of FIG. 1A). Although the integrated column signal and the integrated reference signal are illustrated as a current source in FIG. 3B, they are provided for the convenience of description, and may actually be construed as being a current supplied by the synaptic readout circuit 151 illustrated in FIG. 1B.

The integrated reference signal I_{REF} may flow in toward a node of a capacitor 361-2, and the integrated column signal I_{Cells} may flow out of the same node of the capacitor 361-2. A current I_{net,column} corresponding to a difference between the integrated column signal and the integrated reference signal may flow in the capacitor 361-2 due to the inflow of the integrated reference signal and the outflow of the integrated column signal.

The output circuit 150 may generate, as an output signal (e.g., I_{net,column}), a current corresponding to an integer multiple of a net current that is a difference between a first current I_{P} based on a resistive memory element of a first resistance value and a second current I_{AP} based on a resistive memory element of a second resistance value. The leakage portion circuit 361 may be deactivated while a reset signal RESET is being applied to a switch 361-1 and activated while the reset signal RESET is not being applied to the switch 361-1. That is, the leakage portion circuit 361 may generate the output signal I_{net,column} for a threshold time after the reset signal RESET is not applied.

As the current I_{net,column} flows in the capacitor 361-2, the capacitor 361-2 may be charged, and a voltage of the capacitor 361-2 may be applied to a first terminal (e.g., a (−) terminal) of the operational amplifier OP_{INTEG} 361-3. An output voltage (e.g., V_{LAT}, V_{RFR}, V_{REST}, or V_{GEN}) of the analog mux 365-5 may be applied to a second terminal (e.g., a (+) terminal) of the operational amplifier 361-3. The output voltage of the analog mux 365-5 may be applied to the operational amplifier 361-3 as a common mode input (e.g., V_{CM_COL}).

In an example, an output terminal of the operational amplifier 361-3 may be connected to a window switch 361-4, and the window switch 361-4 may be connected to a capacitor 361-5.

While a window signal WINDOW is being applied to the window switch 361-4, the operational amplifier 361-3 may be connected to the capacitor 361-5. An output current of the operational amplifier 361-3 may flow into the capacitor 361-5 while the window switch 361-4 is closed.

When the window switch 361-4 is opened, the charged capacitor 361-5 may output a voltage V_{INTEG}. The voltage V_{INTEG} of the capacitor 361-5 may leak while a leakage switch 361-6 is closed. In the example of FIG. 3B, a leakage current is indicated as a current source I_{LEAKAGE}.

A current I_{SYNAPSE} may be converted to the voltage V_{INTEG} by the leakage portion circuit 361, and this conversion may be referred to as an integration as described above.

The leakage portion circuit 361 may transmit the voltage V_{INTEG} to the fire and reset portion circuit 365.

A comparator (or an operational amplifier) 365-1 of the fire and reset portion circuit 365 may compare a preset threshold voltage V_{TH} and the voltage V_{INTEG}. The comparator 365-1 may output a fire signal (e.g., FIRE_PULSE=1) when the voltage V_{INTEG} integrated for a threshold time exceeds the threshold voltage V_{TH}, and output a leakage signal (e.g., FIRE_PULSE=0) when the integrated voltage V_{INTEG} is less than or equal to the threshold voltage V_{TH}.

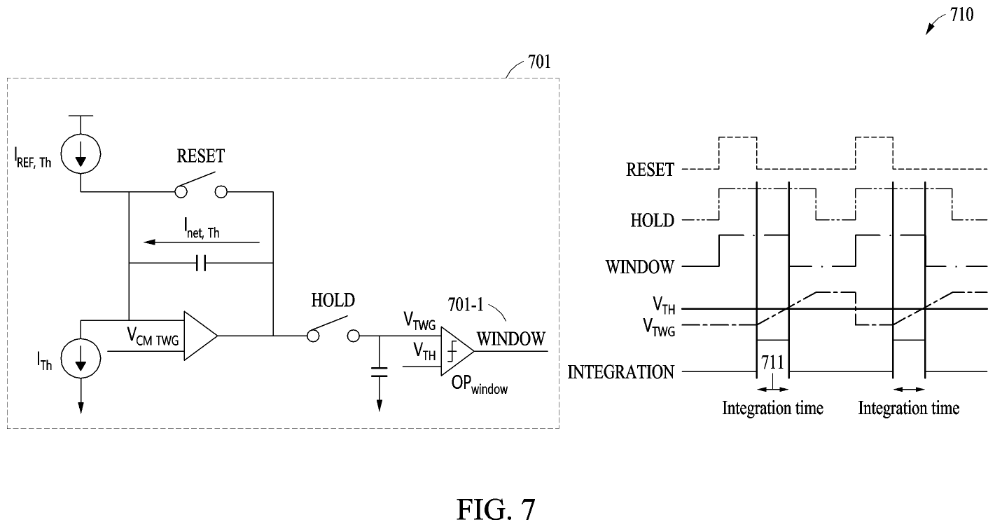

For reference, as will be described below, the threshold time may be set as a time desired until the threshold voltage V_{TH} is reached through a leakage of a threshold current corresponding to a threshold value in a separate circuit (e.g., a threshold time generation circuit). However, the output current and the threshold current are both currents and thus a current-to-current comparison may be difficult. Therefore, the comparator 365-1 of the fire and reset portion circuit 365 may compare the threshold voltage and a voltage that is obtained through a conversion from a current leaked during the threshold time from a point in time at which a RESET signal becomes 0 due to a WINDOW signal generated as will be described below with reference to FIG. 7 to a point in time at which the WINDOW signal becomes 0. When the current is small, an amount of current to be converted to a voltage may be small, and the voltage may thus be less than the threshold voltage. Conversely, when the current is large, an amount of current to be converted to a voltage may also be large, and the voltage may thus increase to be greater than or equal to the threshold voltage, and the comparator 365-1 may output the fire signal.

When the fire signal (e.g., FIRE_PULSE=1) is output in the current clock cycle, the fire signal (e.g., FIRE_PULSE=1) may be transmitted to the OR gate 321, the OR gate 323, and the analog mux 365-5. The OR gate 321 may transmit the LATERAL signal to the neuron circuit 311. In a subsequent clock cycle, the neuron circuit 311 of FIG. 3A may perform a lateral inhibition. The OR gate 323 may transmit the LATERAL signal to the neuron circuit 311. In the subsequent clock cycle, the neuron circuit 313 of FIG. 3A may perform the lateral inhibition. The analog mux 365-5 may determine, adjust, or set the integration start voltage to be V_{RFR} such that the neuron circuit 312 implements a refractory period in the subsequent clock cycle. The integration start voltage of the neuron circuit 312 in the subsequent clock cycle may be V_{RFR}.

The fire signal may be generated as a signal synchronous with a clock signal, through the comparator 365-1 and the flip-flop circuit 365-2 that are synchronous with a clock signal of the current clock cycle.

When the integrated VI_{NTEG} does not exceed the threshold voltage V_{TH}, the leakage portion circuit 361 may perform a leakage. After the performance of the leakage, the fire portion circuit 365 may hold a voltage received from the leakage portion circuit 361, using an operational amplifier 365-3, a switch 365-4, and a capacitor 365-6. The held voltage may be provided as V_{GEN} of the analog mux 365-5. When LATERAL=0, FIRE_PULSE=0, and SEL_RESTIMG=0, the analog mux 365-5 may determine the integration start voltage as V_{GEN}. The integration start voltage of the neuron circuit 312 in the subsequent clock cycle may be V_{GEN}.

In the example of FIG. 3B, a RESET signal of the leakage portion circuit 361, a SW_LEAKAGE signal of the leakage portion circuit 361, and a SW_BUFF signal of the fire and reset portion 365 are control signals, and may be generated by a timing generator 60 that receives a clock signal as an input.

The output circuit 150 may separately perform the integration, the comparison, and the leakage. Accordingly, an error due to constraints in the size of a capacitor and or a leakage current in the output circuit 150 may be minimized. Furthermore, the output circuit 150 may also simulate a fire in the unit of milliseconds (ms), (e.g., alike an actual biological stimulation period).

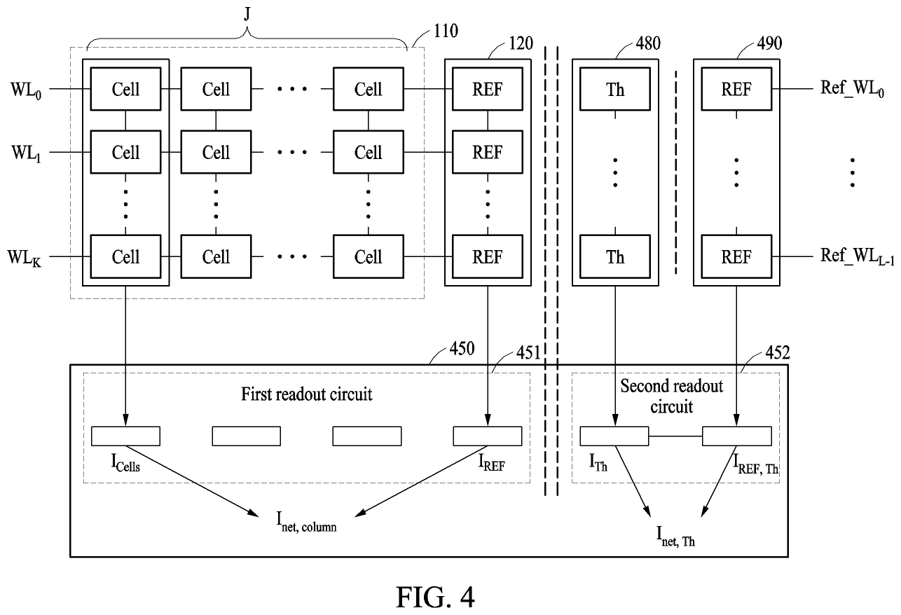

FIG. 4 illustrates an example threshold generation circuit and an additional reference circuit included in an example neural network circuit, in accordance with one or more embodiments.

In an example, the neural network circuit 100 may further include a circuit that sets a threshold value. In an example, the neural network circuit 100 may further include a threshold memory array 480 and an additional reference memory array 490. The synaptic memory array 110 and the reference memory array 120 have been described above with reference to FIG. 1, and a further description thereof will be omitted here.

The threshold memory array 480 may include a plurality of memory elements. At least one memory element set based on a set threshold value among the plurality of memory elements in the threshold memory array 480 may have a first resistance value (e.g., a P state).

A memory cell included in the threshold memory array 480 may be a threshold memory cell which is indicated as Th in FIG. 4. In an example, a memory element that represents the threshold value may be selected based on a bit position. That is, the threshold value may be represented based on the number of memory elements having a first resistance value and a bit position indicated by a corresponding memory element.

The threshold memory array 480 may include threshold memory cells arranged along a column line. The column line may include a plurality of bitlines representing multiple bits. Each of the threshold memory cells may include sub-cells for each bitline. For example, when the threshold value is set as a threshold current of 6I_{P}, a memory element corresponding to a first bit position (e.g., 2¹=2) from an LSB in the threshold memory array 480, and a memory element corresponding to a second bit position (e.g., 2²=4) from the LSB may have the first resistance value, to express (2+4)*I_{P}.

In an example, an additional reference memory cell may share reference wordlines Ref_WL₀ to Ref_WL_{L-1}, with the threshold generation circuit. The additional reference memory cell may have an additional reference memory element that is disposed along a reference wordline and has a second resistance value. A memory element of the additional reference memory cell of the additional reference memory array 490 may have a programmable resistance value according to an implementation. As will be described below, the additional reference memory cell may be used to express, as a net signal, the threshold value set in the threshold memory array 480.

In an example, a signal (hereinafter, a “threshold integrated signal”) integrated along a column of the threshold memory array 480 may be expressed as Equation 6 below.

$${I}_{Th} = {TI}_{P} + ( R - T ) {I}_{AP} \qquad Equation 6$$

In Equation 6, I_{P} denotes a current flowing in a resistive memory element of a P state (e.g., the first resistance value), and I_{AP} denotes a current flowing in a resistive memory element of an AP state (e.g., the second resistance value). A threshold integrated signal I_{Th} may be a linear combination of I_{P} and I_{AP}. In an example, a second readout circuit 452 of an output circuit 450 may generate the threshold integrated signal I_{Th}.

$${I}_{REF , Th} = {YI}_{P} + ( R - Y ) {I}_{AP} \qquad Equation 7$$

Equation 7 may express a signal obtained by applying a bit weight for each bit position to a current signal flowing in a resistive memory element to which a reference word signal is applied among resistive memory elements included in the additional reference memory array 490. An additional integrated reference signal I_{REF,Th} may be a signal obtained by applying a bit weight to a reference signal for each bit position and integrating them. In Equation 7 above, Y may be determined as one of integers less than or equal to R and greater than or equal to 0, according to an implementation. In an example, if the additional reference memory array 490 is configured with 1-bit cells, Y may have a value of 0 or Y.

In an example, the second readout circuit 452 of the output circuit 450 may generate the additional integrated reference signal I_{REF,Th}. In Equations 6 and 7 above, coefficients T and R of the linear combination may be expressed as Equations 8 and 9 below.

$$R = L \cdot ( {2}^{a} - 1 ) \qquad Equation 8$$

$$T = {\sum }_{j = 0}^{k - 1} {\sum }_{i = 0}^{a - 1} {t}_{ij} \cdot {2}^{i} , where T \leq R , {t}_{ij} = 0 or 1 \qquad Equation 9$$

In the equations above, R denotes a value determined based on sub-cells connected to an activated reference wordline. L denotes the number of activated reference wordlines. FIG. 4 illustrates an example in which all reference wordlines are activated. In Equation 9, “a” denotes the number of sub-cells included in each memory cell or the number of bits of a synaptic weight. For example, R may be a sum of values of power of 2 using, as an exponent, a bit position represented by each sub-cell included in a reference memory cell connected to an activated wordline among threshold memory cells connected along a column. T, which is an integer less than or equal to R, may be a value determined based on sub-cells of the P state (e.g., the first resistance value) among the threshold memory cells connected to the activated reference wordline. T may correspond to a preset threshold value. tᵢⱼ may be 1 when an ith threshold memory cell of an activated jth wordline has the first resistance value and may be 0 when the ith threshold memory cell has the second resistance value. In an example, T may be k sums of values of power of 2 using, as an exponent, a bit position represented by a sub-cell of the P state among the threshold memory cells connected to the same column.

$${I}_{net , Th} = {I}_{Th} - {I}_{REF , Th} = ( T - Y ) ( {I}_{P} - {I}_{AP} ) \qquad Equation 10$$

The output circuit 450 of the neural network circuit 100 may generate a threshold net signal I_{net,Th} corresponding to a difference between the threshold integrated signal I_{Th} and the additional integrated reference signal I_{REF,Th} according to Equation 10 above. The output circuit 450 may compare the threshold net signal I_{net,Th} obtained based on Equation 10 above and an output signal I_{net,column} obtained from a first readout circuit 451 (e.g., a circuit including the synaptic readout circuit 151 and the reference readout circuit 152 of FIGS. 1A and 1B) based on Equation 5 described above. However, it may be difficult to implement a circuit for a current-to-current comparison as described above, and thus the output circuit 450 may further include a threshold time generation circuit (or a window signal generation circuit) that indirectly compares the output signal I_{net,column} and the threshold net signal I_{net,Th}. The threshold time generation circuit (or the window signal generation circuit) will be described below with reference to FIG. 7.

The output circuit 450 may apply a threshold time corresponding to a threshold value determined based on a threshold memory cell and an additional reference memory cell to an output signal for an output line and another output signal for another output line. That is, the output circuit 450 may apply a threshold time corresponding to a common threshold to output signals obtained from output lines of a synaptic memory array.

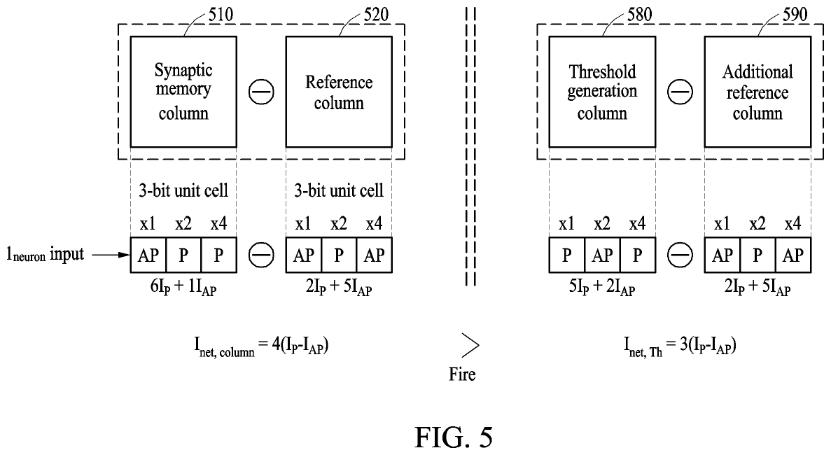

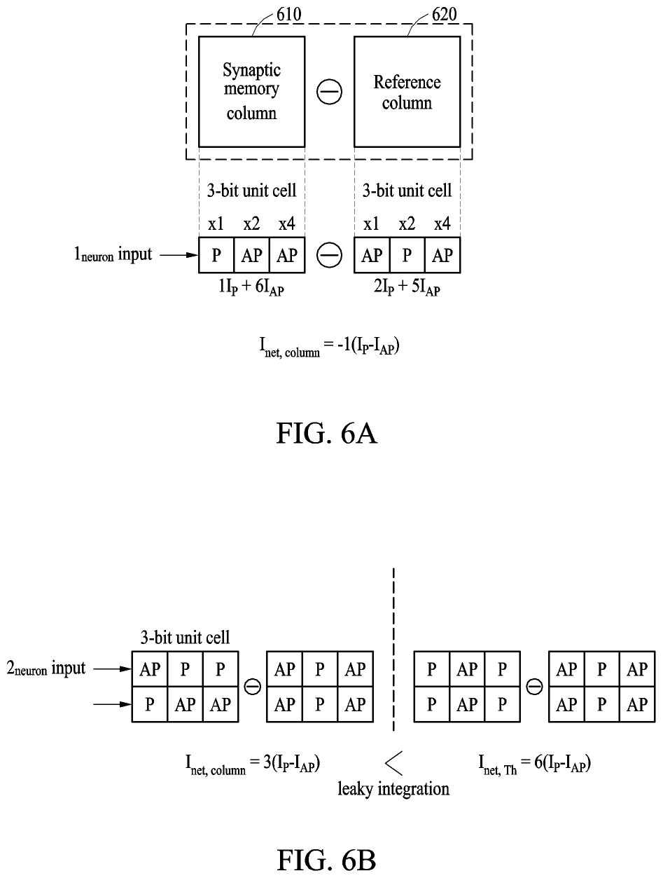

FIGS. 5, and 6A and 6B illustrate examples of a comparison of fires using a net signal generated from a synaptic memory column, a reference column, a threshold generation column, and an additional reference column, in accordance with one or more embodiments.

In the example of FIG. 5, one column of a synaptic memory array is illustrated as a synaptic memory column 510, one column of a reference memory array is illustrated as a reference column 520, one column of a threshold memory array is illustrated as a threshold generation column 580, and one column of an additional reference memory array is illustrated as an additional reference column 590. For the convenience of description, each column may include 3-bit bitlines, and an input signal may be applied to one input line.

In an example, a first sub-cell of the synaptic memory column 510 may have a resistive memory element set to a second resistance value, and a second sub-cell and a third sub-cell thereof may have resistive memory elements set to a first resistance value. Also, a first sub-cell and a third sub-cell of the reference column 520 may have memory elements set to the second resistance value, and a second sub-cell thereof may have a memory element set to the first resistance value. However, these are only examples, and the resistance value of each sub-cell of the reference column 520 is not limited to the foregoing example and may be dynamically changed, such as when synaptic weights are updated or different synaptic weights are subsequently used for a different portion of the neural network.

Each sub-cell may generate a current signal obtained by applying a bit weight (e.g., 1×) corresponding to an LSB, a bit weight (e.g., 2×) of a first bit position from the LSB, and a bit weight (e.g., 4×) of a second bit position from the LSB. That is, the sub-cell corresponding to the LSB may copy a current I_{A}P by a factor of one time according to the bit weight (or a current copy ratio) (e.g., 1×), the sub-cell corresponding to the first bit position from the LSB may copy a current I_{P} by a factor of two times according to the bit weight (or the current copy ratio) (e.g., 2×), and the sub-cell corresponding to the second bit position from the LSB may copy the current I_{P} by a factor of four times according to the bit weight (e.g., 4×). An integrated column signal I_{Cells} of the synaptic memory column 510 may be (2+4)*I_{P}+1*I_{AP}, where * may indicate a multiplication sign. An integrated reference signal I_{REF} of the reference column 520 may be 2*I_{P}+(1+4)*I_{AP}. An output signal I_{net,column} may be 4(I_{P}−I_{AP}). The output signal I_{net,column} is a positive value, and it may thus be verified that the output signal I_{net,column} is an output signal for performing an EPSP operation.

Similarly, a threshold integrated signal I_{T}h in the threshold generation column 580 may be 2*I_{AP}+(1+4)*I_{P}=5I_{P}+2I_{AP}, and an additional integrated reference signal I_{REF,Th} generated in the additional reference column 590 may 2*I_{P}+(1+4)*I_{AP}=2I_{P}+5I_{AP}. In the example of FIG. 5, a threshold net signal I_{net,Th} may be determined to be 3(I_{P}−I_{AP}). In an example, the output signal I_{net,column} may be greater than the threshold net signal I_{net,Th}, and an output circuit may thus generate a fire signal.

Referring to FIG. 6A, a first sub-cell of a synaptic memory column 610 (e.g., the synaptic memory column 510) may have a resistive memory element set to a first resistance value, and a second sub-cell and a third sub-cell thereof may have resistive memory elements set to a second resistance value. Similar to the example of FIG. 5, a first sub-cell and a third sub-cell of a reference column 620 (e.g., the reference column 520) have memory elements set to the second resistance value, and a second sub-cell thereof may have a memory element set to the first resistance value. However, this is only an example, and a resistance value of each sub-cell of the reference column 620 is not limited thereto and may be dynamically changed according to an implementation.

Each sub-cell may generate a current signal in which a bit weight (e.g., 1×) corresponding to an LSB, a bit weight (e.g., 2×) of a first bit position from the LSB, and a bit weight (e.g., 4×) of a second bit position from the LSB are applied. An integrated column signal I_{Cells} of the synaptic memory column 610 may be 1*I_{P}+(2+4)*I_{AP}. An integrated reference signal I_{REF} of the reference column 620 may be 2*I_{P}+(1+4)*I_{AP}. An output signal I_{net,column} may be −1(I_{P}−I_{AP}). The output signal I_{net,column} is a negative value, and it may thus be verified that the output signal I_{net,column} is an output signal to perform an IPSP operation.

FIG. 6B illustrates an example in which an input signal is applied to two input lines, in accordance with one or more embodiments.

In the example of FIG. 6B, an output signal I_{net,column} may be 4(I_{P}−I_{AP})−(I_{P}−I_{AP})=3(I_{P}−I_{AP}) which is a sum of the output signals of FIGS. 5 and 6A. Similarly, a threshold net signal I_{net,Th} may be determined as 6(I_{P}−I_{AP}). The output signal I_{net,column} may be less than the threshold net signal I_{net,Th}, and thus an output circuit may perform a leakage operation.

FIG. 7 illustrates an example threshold time generation circuit of an example neural network circuit, in accordance with one or more embodiments.

In an example, a threshold time generation circuit (or a window signal generation circuit) 701 may set a threshold time (or an integration time) 711 corresponding to a threshold value that is based on a signal generated based on a threshold memory cell and a signal generated based on an additional reference memory cell.

As described above, a direct comparison between an output current and a current set as a threshold value may be difficult, and thus the threshold time generation circuit 701 may set the threshold time 711 for the comparison of currents. The threshold time generation circuit 701 may set, as the threshold time 711, a time used to reach a threshold voltage through a leakage of a current corresponding to the threshold value. As described above, an output circuit may determine whether a time used to reach the same threshold voltage through a leakage of an output current is less than the threshold time 711. For example, the output circuit may indirectly compare the threshold current and the output current by determining whether a voltage V_{INTEG} exceeds the threshold voltage within the set threshold time 711.

The threshold time generation circuit (or the window signal generation circuit) 701 may initiate an integration of a current corresponding to the difference between the signal generated based on the threshold memory cell and the signal generated based on the additional reference memory cell. When a voltage corresponding to the integrated current exceeds the threshold voltage, the threshold time generation circuit (or the window signal generation circuit) 701 may output a signal indicating the threshold time 711 corresponding to the threshold value. For example, the threshold time generation circuit (or the window signal generation circuit) 701 may output a window signal WINDOW 701-1 to a window switch (e.g., the window switch 361-4 of FIG. 3B).

The threshold time generation circuit 701 may have a partially similar configuration to the leakage portion circuit described above with reference to FIG. 3B. In an example, the threshold time generation circuit 701 may allow a threshold integrated signal I_{T}h to flow into a node of a capacitor and allow an additional integrated reference signal I_{REF,Th} to flow out of the node. Therefore, a threshold net signal I_{net,Th} may flow in the capacitor. In an example, capacitors and operational amplifiers may be implemented to be the same in terms of type and size.

Referring again to FIG. 7. a reset signal RESET and a hold signal HOLD in a timing diagram 710 may be generated by a timing generator. In an example, when the reset signal RESET=1, voltages at both ends of a capacitor through which the threshold net signal I_{net,Th} flows may all be V_{CM,TWG} and may thus be initialized. When the reset signal RESET is 0 and the hold signal HOLD is 1, a voltage V_{TWG} obtained through a conversion through an integration according to the threshold net signal I_{net,Th} may be stored in the capacitor. The voltage V_{TWG} may gradually increase based on the integration of the threshold net signal I_{net,Th}. When the voltage V_{TWG} exceeds the threshold voltage V_{TH}, a window comparator OP_{window} may output 0. Accordingly, the threshold time 711 may be defined as a time from a point in time at which the reset signal RESET becomes 0 to a point in time at which the window signal WINDOW 701-1 becomes 0. The voltage V_{CM,TWG} may be set to be less than V_{CM_COLUMN_IN}. For example, if the output signal I_{net,column} and the threshold net signal I_{net,Th} are equal (e.g. I_{net,column}=7I_{P}−7I_{AP}, I_{net,Th}=7I_{P}−7I_{AP)}, it may be verified that there is a firing even in the example of 7I_{P}−7I_{AP}, when a voltage of the converted voltage V_{TWG} based on V_{CM_COLUMN_IN} is greater than the threshold voltage V_{TH} based on V_{CM,TWG}.

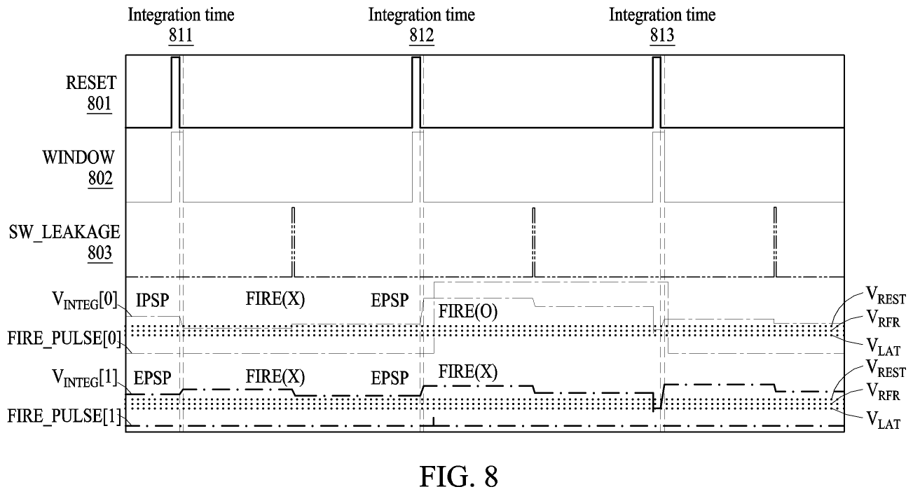

FIG. 8 illustrates an example of operations of example neuron circuits, in accordance with one or more embodiments.

In the example of FIG. 8, a RESET signal 801 and a SW_LEAKAGE signal 803 may be provided to neuron circuits by a timing generator, and a WINDOW signal 802 may be provided to the neuron circuits by a threshold time generation circuit (e.g., the threshold time generation circuit 701).

In the example of FIG. 8, V_{INTEG}[0] and FIRE_PULSE[0] may be, for example, V_{INTEG} and FIRE_PULSE, respectively, of the example neuron circuit 311 described above with reference to FIG. 3A, and V_{INTEG}[1] and FIRE_PULSE[1] may be, for example, V_{INTEG} and FIRE_PULSE, respectively, of the neuron circuit 312 described above with reference to FIG. 3A.

As a first clock cycle starts, a first RESET signal and a first WINDOW signal may be provided to the neuron circuit 311 and the neuron circuit 312.

During an integration time (or a threshold time) 811, V_{INTEG}[0] may decrease. That is, the neuron circuit 311 may implement an IPSP. During the integration time 811, V_{INTEG}[1] may increase. That is, the neuron circuit 312 may implement an EPSP.

V_{INTEG}[0] and V_{INTEG}[1] may be less than V_{TH}, and the neuron circuit 311 and the neuron circuit 312 may not perform a firing.

A first SW_LEAKAGE signal may be provided or applied to the neuron circuit 311 and the neuron circuit 312. A leakage current may be generated in the neuron circuit 312 by the first SW_LEAKAGE signal, and V_{INTEG}[1] may decrease. V_{INTEG}[0] of the neuron circuit 311 may increase without decreasing even in the presence of the SW_LEAKAGE signal 803. Since V_{INTEG}[0] is less than V_{REST} before the first SW_LEAKAGE signal, the neuron circuit 311 may increase V_{INTEG}[0] to be closer to V_{REST} even when in the presence of the first SW_LEAKAGE signal.

The neuron circuit 311 may hold the increased V_{INTEG}[0] and determine the held V_{INTEG}[0] (e.g., V_{GEN}[0]) as a start voltage of an integration (i.e., operation 223 of FIG. 2). Similarly, the neuron circuit 312 may hold the decreased V_{INTEG}[1] and determine the held V_{INTEG}[1] (e.g., V_{GEN}[1]) as the start voltage of the integration (i.e., operation 223 of FIG. 2).

As a second clock cycle starts, a second RESET signal and a second WINDOW signal may be provided to the neuron circuit 311 and the neuron circuit 312.

During an integration time (or a threshold time) 812, each of the neuron circuit 311 and the neuron circuit 312 may integrate voltages from the determined start voltage. The neuron circuit 311 may integrate voltages from the held V_{INTEG}[0] as the start voltage, and the neuron circuit 312 may integrate voltages from the held V_{INTEG}[1] as the start voltage. During the integration time 812, V_{INTEG}[0] and V_{INTEG}[1] may increase.

V_{INTEG}[0] may exceed V_{TH}, and thus the neuron circuit 311 may perform a fire. V_{INTEG}[1] may be less than V_{TH}, and thus the neuron circuit 312 may not perform a fire.

A second SW_LEAKAGE signal may be provided to the neuron circuit 311 and the neuron circuit 312, and each of the neuron circuit 311 and the neuron circuit 312 may perform a leakage. By this leakage, V_{INTEG}[0] and V_{INTEG}[1] may decrease.

Since the neuron circuit 311 performs the fire in the second clock cycle (i.e., FIRE_PULSE[0]=1), the neuron circuit 311 may set the start voltage of the integration to V_{RFR}(i.e., operation 217 of FIG. 2). Accordingly, in a subsequent clock cycle (i.e., a third clock cycle), the integration of the neuron circuit 311 may start from V_{RFR}.

Since the neuron circuit 311 performs the fire in the second clock cycle (i.e., LATERAL=1), the neuron circuit 312 may set the start voltage of the integration of the neuron circuit 312 to V_{LAT}. Accordingly, in the third clock cycle, the integration of the neuron circuit 312 may start from V_{RFR}.

As the third clock cycle starts, a third RESET signal and a third WINDOW signal may be provided to the neuron circuit 311 and the neuron circuit 312.

During an integration time (or a threshold time) 813, each of the neuron circuit 311 and the neuron circuit 312 may integrate voltages from the determined start voltage.

Since the start voltage of the integration of the neuron circuit 311 is determined as V_{RFR}, the neuron circuit 311 may start integrating voltages from V_{RFR}. V_{INTEG} [0] may start increasing from V_{RFR} during the integration time 813. Since the integration of the neuron circuit 311 during the integration time 813 starts from a relatively low voltage, for example, V_{RFR}, the neuron circuit 311 may implement a refractory period in a biological neural network.

Since the start voltage of the integration of the neuron circuit 312 is determined as V_{LAT}, the neuron circuit 312 may start integrating voltages from V_{LAT}. V_{INTEG}[1] may start increasing from V_{LAT} during the integration time 813. Since the integration of the neuron circuit 312 during the integration time 813 starts from a relatively low voltage, for example, V_{LAT}, the neuron circuit 312 may implement a lateral inhibition and not perform a firing.

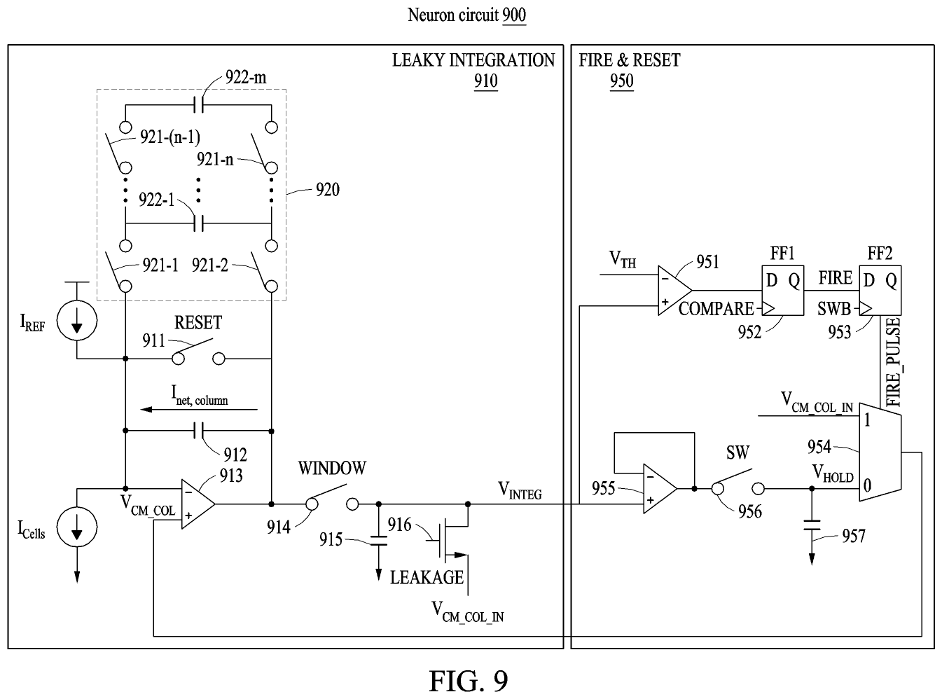

FIG. 9 illustrates an example of implementing a lateral inhibition by an example neural network circuit, in accordance with one or more embodiments.

A neuron circuit 900 of FIG. 9 may correspond to any one, any combination, or each of neuron circuits included in the output circuit 150, as a non-limiting example. For example, the neuron circuit 900 of FIG. 9 may correspond to each of the neuron circuits 311 to 314 described above with reference to FIG. 3A.

Referring to FIG. 9, the neuron circuit 900 may include a leakage portion circuit or a leaky integration 910 and a fire and reset portion circuit 950.

In an example, when another neuron circuit performs a fire in a previous clock cycle, the other neuron circuit (or an OR gate of the other neuron circuit) may transmit a LATERAL signal to the neuron circuit 900.

When receiving the LATERAL signal from the other neuron circuit, the neuron circuit 900 may control a capacitor network 920 such that one or more capacitors are connected in parallel with a capacitor 912, and may therefore reduce a speed at which a current (e.g., I_{net,column} of FIG. 9) is converted to a voltage (e.g., V_{INTEG}). When the one or more capacitors are connected in parallel to the capacitor 912, a total capacitance of the capacitors connected in parallel may become greater than a capacitance of the capacitor 912, and thus the speed at which the current (e.g., I_{net,column} of FIG. 9) is converted to the voltage (e.g., V_{INTEG}) may be reduced.

In an example, when receiving a LATERAL signal from another neuron circuit, the neuron circuit 900 may turn on some or all of switches 921-1 to 921-n in the capacitor network 920 to connect one or more of or all of capacitors 922-1 to 922-m in parallel to the capacitor 912. For the implementation of the lateral inhibition, the number of capacitors to be connected in parallel to the capacitor 912 among the capacitors 922-1 to 922-m in the capacitor network 920 may be determined in advance. Hereinafter, for the convenience of description, the capacitor 922-1 among the capacitors 922-1 to 922-m in the capacitor network 920 may be connected in parallel to the capacitor 912, and the remaining capacitors among the capacitors 922-1 to 922-m may not be connected in parallel to the capacitor 912.

The leakage portion circuit 910 may receive an integrated column signal I_{cells} and an integrated reference signal I_{REF} from a synaptic readout circuit.

The integrated reference signal I_{REF} may flow into nodes of the capacitor 912 and the capacitor 922-1 of the leakage portion circuit 910, and the integrated column signal I_{Cells} may flow out of the same nodes. Accordingly, a current I_{net,column} (e.g., I_{net,column} described above with reference to Equation 5) corresponding to a difference between the integrated column signal and the integrated reference signal may flow in the capacitor 912 and the capacitor 922-1.

In an example, the leakage portion circuit 910 may be deactivated while a reset signal RESET is being applied to a reset switch 911, and may be activated while the reset signal RESET is not being applied to the switch 911.

The current I_{net,column} may flow in the capacitor 912 and the capacitor 922-1 during an integration time (e.g., a time for which the switch 911 is turned off and a switch 914 is turned on), and an output voltage of the capacitor 912 and the capacitor 922-1 may be applied or may be input to a first terminal (e.g., a (−) terminal) of an operational amplifier 913. An output voltage (e.g., V_{CM_COL_IN} or V_{HOLD}) of a mux 954 of the fire portion circuit 950 may be applied or input to a second terminal (e.g., a (+) terminal) of the operational amplifier 913.

An output terminal of the operational amplifier 913 may be connected a window switch 914, and the window switch 914 may be connected to a capacitor 915. The operational amplifier 913 may be connected to the capacitor 915 while a window signal WINDOW is being applied to the window switch 914.

An output current of the operational amplifier 913 may flow into the capacitor 915 during an integration time (e.g., a time for which the window switch 914 is turned on after the switch 911 is turned off).

The capacitor 915 may convert the output current of the operational amplifier 913 to a voltage V_{INTEG}. V_{INTEG}, an output voltage of the capacitor 915, may be leaked by a leakage transistor LEAKAGE 916 when the leakage transistor LEAKAGE 916 is turned on.

The leakage portion circuit 910 may transmit the voltage V_{INTEG} to the fire portion circuit 950.

In the fire and reset portion circuit 950, a comparator 951 may compare a preset threshold voltage V_{TH} and the converted voltage V_{INTEG}. The comparator 951 may output a fire signal (e.g., FIRE_PULSE=1) when the converted voltage V_{INTEG} exceeds the threshold voltage V_{TH}, and may output a leakage signal (e.g., FIRE_PULSE=0) when the converted voltage V_{INTEG} is less than or equal to the threshold voltage V_{TH}.

When the fire signal is output from the comparator 951, the fire signal may be input as a control signal or a selection signal to the mux 954 through respective flip-flops 952 and 953.

The mux 954 may initialize a common mode voltage of the operational amplifier 913 by transmitting a voltage V_{CM_COL_IN} input from the outside to the operational amplifier 913 in response to the reception of the fire signal. In a subsequent clock cycle, a start voltage of an integration of the neuron circuit 900 may then be V_{CM_COL_IN}.

When the voltage V_{INTEG} is less than or equal to the threshold voltage V_{TH}, the fire portion circuit 950 may perform a leakage. The voltage V_{INTEG} may change based on the leakage, and the fire portion circuit 950 may hold or maintain the changed voltage through an operational amplifier 955, a switch 956, and a capacitor 957. The held voltage may be represented as V_{HOLD} in the fire portion circuit 950 of FIG. 9. When the mux 954 is not receiving the fire signal from the flip-flop 953, the mux 954 may transmit the voltage V_{HOLD} to the operational amplifier 913. In the subsequent clock cycle, the start voltage of the integration of the neuron circuit 900 may then be V_{HOLD}.

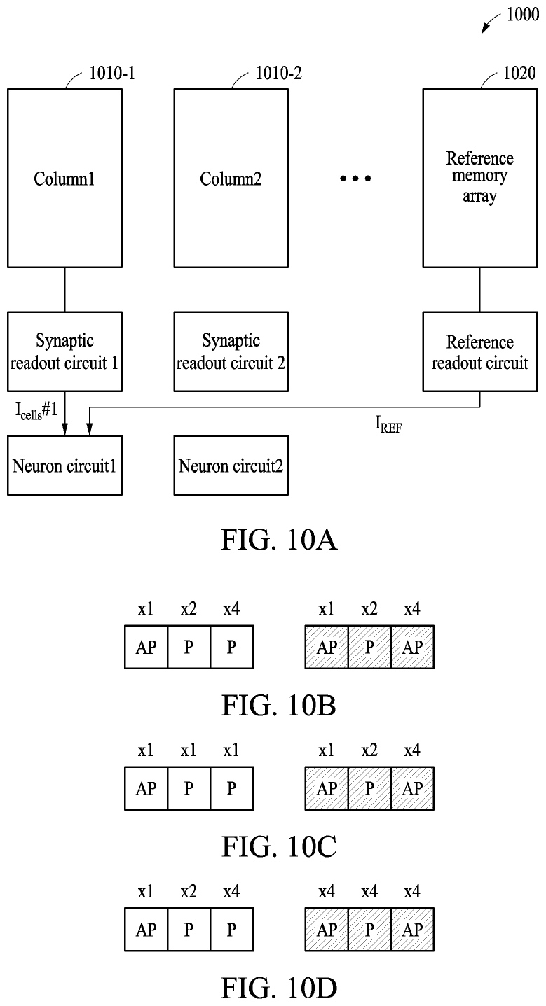

FIGS. 10A through 10D illustrate an example of implementing a lateral inhibition by an example neural network circuit, in accordance with one or more embodiments.

An example neural network circuit 1000 of FIG. 10A may include a synaptic memory array (e.g., the synaptic memory array 110 of FIG. 1A), a reference memory array 1020 (e.g., the reference memory array 120 of FIG. 1A), a plurality of synaptic readout circuits, a reference readout circuit, and a plurality of neuron circuits. The plurality of synaptic readout circuits, the reference readout circuit, and the plurality of neuron circuits of FIG. 10A may correspond to the components of the output circuit 150 described above.

Each of column 1 1010-1 and column 2 1010-2 may correspond to a synaptic memory cell. In an example, column 1 1010-1 may correspond to a synaptic memory cell 111 described above.

In an example, when neuron circuit 2 of FIG. 10A performs a firing in a previous clock cycle, the neural network circuit 1000 may operate to decrease the magnitude of I_{net,column} of neuron circuit 1. Accordingly, neuron circuit 1 may implement or perform a lateral inhibition in a current clock cycle. The decreasing of the magnitude of I_{net,column} of neuron circuit 1 will be described in detail below with reference to FIGS. 10B and 10C.

A synaptic weight set and a reference weight set are illustrated in FIG. 10B. The synaptic weight set is illustrated on a left side of FIG. 10B, and the reference weight set is illustrated on a right side of FIG. 10B.

When neuron circuit 1 does not receive a LATERAL signal from another neuron circuit (e.g., neuron circuit 2), column 1 1010-1 may operate similarly to the synaptic memory column 510 of FIG. 5. Column 1 1010-1 may copy a current corresponding to each bit according to the synaptic weight set (or a current copy ratio) (e.g., 1, 2, 4). Synaptic readout circuit 1 may read 6*I_{P}+1*I_{AP} from column 1 1010-1 and transmit I_{cells} #1=6*I_{P}+1*I_{AP} to neuron circuit 1. The reference memory array 1020 may operate similarly to the reference column 520 of FIG. 5. The reference memory array 1020 may copy a current corresponding to each bit according to the reference weight set (or a current copy ratio) (e.g., 1, 2, 4). The reference reading circuit may read 2*I_{P}+5*I_{AP} from the reference memory array 1020 and transmit I_{REF}=2*I_{P}+5*I_{AP} to neuron circuit 1. Neuron circuit 1 may then generate I_{net,column}=4(I_{P}−I_{AP}).

In an example, neuron circuit 1 may receive a LATERAL signal from another neuron circuit (e.g., neuron circuit 2). In this case, the neural network circuit 1000 may adjust the synaptic weight set and/or the reference weight set of FIG. 10B.

In an example, when neuron circuit 1 receives a LATERAL signal from neuron circuit 2 in a first clock cycle, the neural network circuit 1000 may replace or change the synaptic weight set of FIG. 10B with one (e.g., a synaptic weight set (1, 1, 1) of FIG. 10C) selected from among a plurality of synaptic weight sets to allow neuron circuit 1 to perform a lateral inhibition in a subsequent clock cycle (i.e., a second clock cycle). The synaptic weight set (1, 1, 1) of FIG. 10C may be smaller than the synaptic weight set (1, 2, 4) of FIG. 10B, and I_{net,column} of neuron circuit 1 in the second clock cycle may be smaller than I_{net,column} of neuron circuit 1 in the first clock cycle. Accordingly, a degree of conversion from the current I_{net,column} to a voltage V_{INTEG} in the second clock cycle may be reduced, and the lateral inhibition of neuron circuit 1 may therefore be implemented.

In another example, when neuron circuit 1 receives a LATERAL signal from neuron circuit 2 in the first clock cycle, the neural network circuit 1000 may replace or change the reference weight set of FIG. 10B with one (e.g., a reference weight set (4, 4, 4) of FIG. 10D) selected from among a plurality of reference weight sets to allow neuron circuit 1 to perform a lateral inhibition in the subsequent clock cycle (i.e., the second clock cycle). The reference weight set (4, 4, 4) of FIG. 10D may be greater than the reference weight set (1, 2, 4) of FIG. 10B, and I_{net,column} of neuron circuit 1 in the second clock cycle may be smaller than I_{net,column} of neuron circuit 1 in the first clock cycle. Accordingly, a degree of conversion from the current I_{net,column} to the voltage V_{INTEG} in the second clock cycle may be reduced, and the lateral inhibition of neuron circuit 1 may therefore be implemented.

According to an example, the neural network circuit 1000 may adjust both the synaptic weight set and the reference weight set to reduce I_{net,column} of neuron circuit 1. In an example, the neural network circuit 1000 may adjust the synaptic weight set to be smaller than the synaptic weight set of FIG. 10B, and may adjust the reference weight set to be greater than the reference weight set of FIG. 10B.

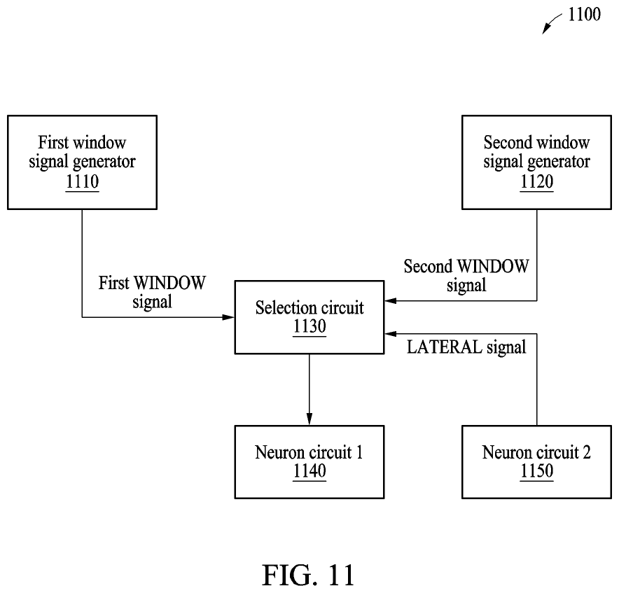

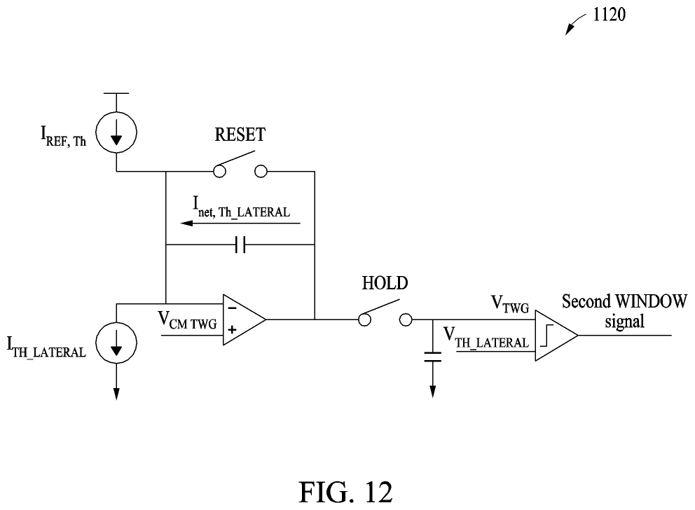

FIGS. 11 and 12 illustrate an example of implementing a lateral inhibition by an example neural network circuit, in accordance with one or more embodiments.

Referring to FIG. 11, an example neural network circuit 1100 may include a plurality of window signal generators 1110 and 1120 and a selection circuit 1130. Although not illustrated in FIG. 11, the neural network circuit 1100 may also include a synaptic memory array (e.g., the synaptic memory array 110 of FIG. 1A), a reference memory array (e.g., the reference memory array 120 of FIG. 1A), and an output circuit (e.g., the output circuit 150 of FIG. 1A). In an example, neuron circuit 1 1140 and neuron circuit 2 1150 of FIG. 11 may be included in the output circuit 150.

The first window signal generator 1110 may generate a first WINDOW signal and transmit the generated first WINDOW signal to the selection circuit 1130. The second window signal generator 1120 may generate a second WINDOW signal and transmit the generated second WINDOW signal to the selection circuit 1130. In an example, the first WINDOW signal and the second WINDOW signal may be synchronized with a clock signal, and a point in time at which the second WINDOW signal becomes 0 may be earlier than a point in time at which the first WINDOW signal becomes 0. In an example, a width of the second WINDOW signal may be narrower than a width of the first WINDOW signal. Accordingly, a time for an integration to be performed when a neuron circuit receives the second WINDOW signal may be shorter than a time for an integration to be performed when the first WINDOW signal is applied.

In a first clock cycle, neuron circuit 2 1150 may perform a fire. Neuron circuit 2 1150 may transmit a LATERAL signal to the selection circuit 1130.

When receiving the LATERAL signal from the neuron circuit 2 1150, the selection circuit 1130 may transmit the second WINDOW signal, instead of the first WINDOW signal, to neuron circuit 1 1140 in a second clock cycle. An integration time of neuron circuit 1 1140 in the second clock cycle may be less than an integration time of neuron circuit 1 1140 in the first clock cycle in which the first WINDOW signal is applied. Accordingly, a lateral inhibition of neuron circuit 1 1140 may be implemented.

The first window signal generator 1110 may correspond to the threshold time generation circuit 701 described above with reference to FIG. 7. The second window signal generator 1110 may have the same structure as the threshold time generation circuit 701, as illustrated in FIG. 12. In this example, I_{TH_LATERAL} of FIG. 12 may be greater than I_{TH} of FIG. 7, and V_{TH_LARTEL} of FIG. 12 may be less than V_{TH} of FIG. 7. The integration time of neuron circuit 1 1140 to which the second WINDOW signal is applied may be shorter than the integration time of neuron circuit 1 1140 to which the first WINDOW signal is applied.

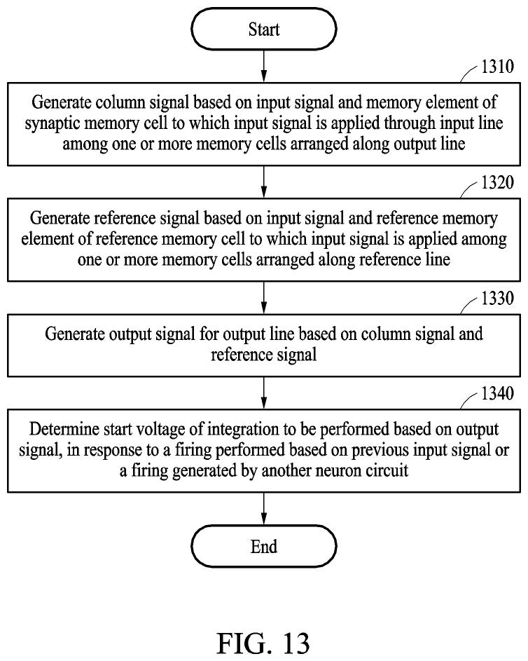

FIG. 13 illustrates an example method of operating an example neural network circuit, in accordance with one or more embodiments. The operations in FIG. 13 may be performed in the sequence and manner as shown. However, the order of some operations may be changed, or some of the operations may be omitted, without departing from the spirit and scope of the shown example. Additionally, operations illustrated in FIG. 13 may be performed in parallel or simultaneously. In addition to the description of FIG. 13 below, the descriptions of FIGS. 1A-12 may also be applicable to FIG. 13 and are incorporated herein by reference, and thus the above description may not be repeated here for brevity purposes.

Referring to FIG. 13, in operation 1310, a neural network circuit (e.g., the neural network circuit 100 of FIG. 1, the neural network circuit 1000 of FIG. 10A, or the neural network circuit 1100 of FIG. 11) may generate a column signal, based on a memory element of a synaptic memory cell (e.g., the synaptic memory cell 111) to which an input signal is applied through an input line among one or more memory cells arranged along an output line and on the input signal.

In operation 1320, the neural network circuit may generate a reference signal, based on a reference memory element of a reference memory cell to which the input signal is applied among one or more memory cells arranged along a reference line and on the input signal.

In operation 1330, the neural network circuit may generate an output signal for the output line based on the column signal and the reference signal.

In operation 1340, the neural network circuit may determine a start voltage of integration to be performed based on the output signal, when a firing is performed based on a previous input signal and when a firing is performed by another neuron circuit. In an example, when the integration is performed in a second clock cycle (or a current clock cycle), the previous input signal may be, for example, an input signal that is applied to the input line in a previous clock cycle of the second clock cycle, i.e., a first clock cycle.

For example, in operation 1340, a neuron circuit (e.g., the neuron circuit 312 in FIG. 3A) of the neural network circuit may determine, as a first voltage (e.g., V_{LAT}), the start voltage of the integration based on a firing performed by another neuron circuit (e.g., the neuron circuit 311 or the neuron circuit 313 of FIG. 3A), and may determine, as a second voltage (e.g., V_{RFR}), the start voltage of the integration based on a firing performed by the neuron circuit. When the input signal is a signal initially applied to the input line (e.g., SEL_RESTING=1), the neuron circuit may determine the start voltage of the integration as a third voltage (e.g., V_{REST}). Among the first voltage, the second voltage, and the third voltage, the third voltage may be the largest and the first voltage may be the smallest. The neuron circuit may determine the start voltage of the integration as a fourth voltage (e.g., V_{GEN}), when the firing is not performed by the other neuron circuit and the firing is not performed based on the previous input signal, and the input signal is not the signal initially applied to the input line (i.e., LATERAL=0, FIRE_PULSE=0, and SEL_RESTING=0).

The neural network circuit (or the neuron circuit) may perform a leakage when a voltage (e.g., V_{INTEG}) integrated from the determined start voltage (e.g., the first voltage, the second voltage, the third voltage, or the fourth voltage) based on the output signal is less than a threshold voltage (e.g., V_{TH}), and may perform a fire when the integrated voltage is equal to the threshold voltage.

In an example, a memory element of a synaptic memory cell may be a resistive memory element, and this memory element may have one of a first resistance value and a second resistance value. A reference memory element may be a resistive memory element and may have one of the first resistance value and the second resistance value. A neuron circuit may generate, as an output signal (e.g., I_{net, column}), a current corresponding to a positive integer multiple (or a negative integer multiple) of a net current, which is a difference between a first current that is based on a memory element of the first resistance value and a second current that is based on a memory element of the second resistance value.

The example neuron circuit may generate an integrated column signal (e.g., I_{cells}) by integrating column signals for respective bits of the synaptic memory cell, generate an integrated reference signal (e.g., I_{REF}) by integrating reference signals for respective bits of the reference memory cell, and generate the output signal (e.g., I_{net,column}) corresponding to a difference between the integrated column signal and the integrated reference signal.

In an example, the neural network circuit may further include a threshold memory array and an additional reference memory cell. The threshold memory array may include a plurality of memory elements, among which at least one memory element set based on a set threshold value may have the first resistance value. The reference memory cell may share a reference wordline with the threshold memory array and may have an additional reference memory element disposed along the reference wordline and having the second resistance value.

In an example, the neuron circuit may include a capacitor (e.g., the capacitor 361-2) configured to convert a current (e.g., I_{net,column}) corresponding to the output signal to a voltage, and an operational amplifier (e.g., the operational amplifier 361-3) configured to receive the converted voltage and the determined start voltage and output a voltage.

In an example, as described above with reference to FIG. 9, the neuron circuit may include switches (e.g., the switches 921-1 to 921-n) and one or more additional capacitors that are connectable in parallel to the capacitor (e.g., the capacitor 912 of FIG. 9) through the switches (e.g., the switches 921-1 to 921-n). When there is a firing by another neuron circuit, the neuron circuit may turn on all or some of the switches (e.g., the switches 921-1 to 921-n), which is described above with reference to FIG. 9, and a detailed description thereof will be omitted here for conciseness.

In an example, the neural network circuit may include a current mirror configured to copy the column signal according to a first copy ratio and copy the reference signal according to a second copy ratio, which is described above with reference to FIG. 5, and a detailed description thereof will be omitted here for conciseness.

In an example, when there is a firing by another neuron circuit, the neural network circuit may adjust at least one of the first copy ratio or the second copy ratio. For example, as described above with reference to FIG. 10C, the neural network circuit may adjust the first copy ratio of each column signal (e.g., a current corresponding to each bit) of column 1 1010-1 from a copy ratio (1, 2, 4) to a copy ratio (1, 1, 1). As described above with reference to FIG. 10D, the neural network circuit may adjust the second copy ratio of each column signal (e.g., a current corresponding to each bit) of one column of the reference memory array 1020 from a copy ratio (1, 2, 4) to a copy ratio (4, 4, 4).

In an example, the neural network circuit may include a first window signal generation circuit (e.g., the first window signal generator 1110 of FIG. 11) configured to generate a first window signal to set a time interval in which an integration is performed, a second window signal generation circuit (e.g., the second window signal generator 1120 of FIG. 11) configured to generate a second window signal having a smaller pulse width than a pulse width of the first window signal, and a selection circuit (e.g., the selection circuit 1130 of FIG. 11) configured to transmit the second window signal to the neuron circuit when a fire is generated on another neuron circuit and transmit the first window signal when a fire is not generated on another neuron circuit.

The technical descriptions provided above with reference to FIGS. 1A through 12 may also apply to the method of operating the neural network circuit of FIG. 13.

The neural network circuit 100, and other circuitries, components and devices of FIGS. 1-13, and other circuitries, components or devices described herein are implemented as, and by, hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to control the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods that perform the operations described in this application, and illustrated in FIGS. 1-13, are performed by computing hardware, for example, by one or more processors or computers, implemented as described above executing instructions or software to control the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller, e.g., as respective operations of processor implemented methods. One or more processors, or a processor and a controller, may perform a single operation, or two or more operations.

Instructions or software to control computing hardware, for example, one or more processors or computers, to control the neural network circuits or circuitry to perform the methods as described above may be written as computer programs, code segments, instructions or any combination thereof, for individually or collectively instructing or configuring the one or more processors or computers to operate as a machine or special-purpose computer to perform such control of the operations that be performed by the neural network circuits or circuitry and the methods as described above. In one example, the instructions or software include machine code that is directly executed by the one or more processors or computers, such as machine code produced by a compiler. In another example, the instructions or software include higher-level code that is executed by the one or more processors or computers using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the control of hardware components to perform the methods as described above, and any associated data, data files, and data structures, may be recorded, stored, or fixed in or on one or more non-transitory computer-readable storage media, such as in memory 20 of FIG. 1. Examples of a non-transitory computer-readable storage medium include read-only memory (ROM), random-access programmable read only memory (PROM), EEPROM, RAM, DRAM, SRAM, flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors and computers so that the one or more processors and computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electronic device with neural network circuitry, comprising:
a synaptic memory cell, comprising a memory element disposed along an output line within the neural network circuitry, and configured to, dependent on the memory element and an input signal applied to an input line within the neural network circuitry, perform a generation of a column signal on the output line;
a reference memory cell comprising a reference memory element disposed along a reference line within the neural network circuitry, and configured to, dependent on the reference memory element and the input signal, perform a generation of a reference signal on the reference line; and
a first neuron circuit configured to generate an output signal based on the column signal and the reference signal, and determine a start voltage of an integration that is to be performed based on the output signal in response to a previous firing by the first neuron circuit with respect to a previous input signal or another firing being performed by a second neuron circuit.

2. The electronic device of claim 1, wherein the first neuron circuit is configured to:
determine the start voltage as a first voltage based on the other firing, determine the start voltage as a second voltage based on the previous firing, and determine the start voltage as a third voltage in response to the input signal being a signal that is initially applied to the input line.

3. The electronic device of claim 2, wherein, among the first voltage, the second voltage, and the third voltage, the third voltage is a largest voltage and the first voltage is a smallest voltage.

4. The circuit of claim 2, wherein the first neuron circuit is configured to:
determine the start voltage as a fourth voltage, in response to the other firing not being performed by the second neuron circuit, the previous firing not being performed by the first neuron circuit based on the previous input signal, and the input signal not being the signal initially applied to the input line.

5. The electronic device of claim 1, wherein the first neuron circuit is configured to:
perform a leakage operation when a voltage integrated from the determined start voltage based on the output signal does not meet a threshold voltage, and perform a fire when the integrated voltage meets the threshold voltage.

6. The electronic device of claim 1, wherein memory element is configured to have a first resistance value at one time and a second resistance value at another time.

7. The electronic device of claim 6, wherein the first neuron circuit is configured to:
generate, as the output signal, a current corresponding to a positive integer multiple of a net current which is a difference between a first current that is based on the memory element having the first resistance value and a second current that is based on the memory element having the second resistance value.

8. The electronic device of claim 6, wherein the first neuron circuit is configured to:
generate, as the output signal, a current corresponding to a negative integer multiple of a net current which is a difference between a first current that is based on the memory element having the first resistance value, and a second current that is based on the memory element having the second resistance value.

9. The electronic device of claim 1, wherein the first neuron circuit is configured to:
generate an integrated column signal by integrating column signals for respective bits of the synaptic memory cell, generate an integrated reference signal by integrating reference signals for respective bits of the reference memory cell, and generate the output signal corresponding to a difference between the integrated column signal and the integrated reference signal.

10. The electronic device of claim 1, further comprising:
a threshold memory array comprising a plurality of memory elements of which at least one memory element set based on a threshold value among the plurality of memory elements is configured to have a first resistance value; and
an additional reference memory cell configured to share a reference wordline with the threshold memory array and comprising an additional reference memory element disposed along the reference wordline and configured to have a second resistance value.

11. The electronic device of claim 1, wherein the first neuron circuit comprises:
a first capacitor configured to convert a current corresponding to the output signal to a first capacitor voltage; and
an operational amplifier configured to receive the first capacitor voltage and the determined start voltage and output a voltage.

12. The electronic device of claim 11, wherein the first neuron circuit further comprises:
one or more switches; and
one or more second capacitors that are connected in parallel with the first capacitor through the one or more switches,
wherein the first neuron circuit is configured to turn on all or some of the one or more switches in response to the other firing being performed by the second neuron circuit.

13. The electronic device of claim 1, comprising:
a current mirror configured to copy the column signal based on a first copy ratio, and copy the reference signal based on a second copy ratio.

14. The electronic device of claim 13, further configured to:
adjust at least one of the first copy ratio and the second copy ratio in response to the other firing being performed by the second neuron circuit.

15. The electronic device of claim 1, further comprising:
a first window signal generation circuit configured to generate a first window signal to set a time interval for which the integration is performed;
a second window signal generation circuit configured to generate a second window signal having a pulse width less than a pulse width of the first window signal; and
a selection circuit configured to transmit the second window signal to the first neuron circuit in response to the other firing being performed by the second neuron circuit and transmit the first window signal to the first neuron circuit in response to the other firing not being performed by the second neuron circuit.

16. The electronic device of claim 1, wherein the synaptic memory cell comprises:
resistive memory elements corresponding to a number of bits that represent a synaptic weight assigned to the synaptic memory cell,
wherein the resistive memory elements are arranged along the same input line.

17. The electronic device of claim 16, wherein the reference memory cell comprises:
reference memory elements corresponding to the number of bits,
wherein the reference memory elements are arranged along the input line.

18. A method of operating a neural network circuit, comprising:
performing a generation of a column signal on an output line within the neural network circuitry dependent on a memory element of a synaptic memory cell to which an input signal is applied to an input line within the neural network circuitry among one or more memory cells arranged along the output line and on the input signal;
performing a generation of a reference signal on a reference line within the neural network circuitry dependent on a reference memory element of a reference memory cell to which the input signal is applied among one or more memory cells arranged along the reference line and on the input signal;
generating, by a first neuron circuit, an output signal based on the generated column signal and the generated reference signal; and
determining a start voltage of an integration that is to be performed based on the output signal, in response to a previous firing by the first neuron circuit with respect to a previous input signal or another firing being performed by a second neuron circuit.

19. The method of claim 18, wherein the determining of the start voltage comprises:
determining the start voltage as a first voltage based on the other firing, determining the start voltage as a second voltage based on the previous firing, and determining the start voltage as a third voltage in response to the input signal being a signal that is initially applied to the input line.

20. The method of claim 19, wherein the determining comprises:
determining the start voltage as a fourth voltage, in response to other firing not being performed by the second neuron circuit, the previous firing not being performed by the first neuron circuit based on the previous input signal, and the input signal not being the signal initially applied to the input line.
